(19) United States
(12) Patent Application Publication
(10) Pub. No.: US 2026/0304765 A1
(43) Pub. Date: Oct. 1, 2026

(54) MEMORY DEVICES HAVING PILLAR INTERIOR SELECT

(71) Applicant: Micron Technology, Inc., Boise, ID (US)

(72) Inventors: Darwin A. Clampitt, Wilder, ID (US); Collin Howder, Boise, ID (US); Vladimir Samara, Boise, ID (US)

(21) Appl. No.: 19/092,634

(22) Filed: Mar. 27, 2025

(51) Int. Cl. H10B 43/27; G11C 16/04; H10B 41/10; H10B 41/27; H10B 41/35; H10B 43/10; H10B 43/35; H10D 64/66

(52) U.S. Cl. CPC H10B 43/27; G11C 16/0483; H10B 41/10; H10B 41/27; H10B 41/35; H10B 43/10; H10B 43/35; H10D 64/665

(57) ABSTRACT

A variety of applications can include a memory device having an array of pillars with memory cells arranged in tiers along the pillars. Drain-side select gate (SGD) transistors can be structured substantially in the pillar at a level above the memory cells. The gate of the SGD transistor can be formed in the center of the respective pillar. In various arrangements, the gate of a SGD transistor interior to a pillar of memory cells can be arranged to operate with dual channels of the pillar. Additional devices, systems, and methods are discussed.

### FIELD OF THE DISCLOSURE

Embodiments of the disclosure relate generally to memory devices and, more specifically, to arrangements of select devices with respect to memory cells of the memory devices and methods of formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices and other electronic devices can be improved by enhancements to the structure and fabrication of components in the memory devices to access storage units of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a representation a pillar arrangement in a memory device having a drain-side select gate transistor in a pillar with memory cells arranged in tiers along the pillar, in accordance with various embodiments.

FIG. 2 is representation a pillar arrangement in a memory device having a drain-side select gate transistor in a pillar with memory cells arranged in tiers along the pillar structured as multiple decks of memory cells, in accordance with various embodiments.

FIG. 3 is a flow diagram of features of an example method 300 of forming a memory device, in accordance with various embodiments.

FIGS. 4-54 illustrate features of an example process flow of fabricating a memory device having an array of memory cells structured as an array of pillars, with memory cells arranged in tiers along the pillars and a drain-side select gate transistor in an interior to each pillar, in accordance with various embodiments.

FIG. 55 illustrates a block diagram of an example machine having one or more embodiments of memory devices as discussed herein, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. The various embodiments are not necessarily mutually exclusive, as some embodiments can be combined with one or more other embodiments to form new embodiments. The following detailed description is, therefore, not to be taken in a limiting sense.

Flash memory is utilized as non-volatile memory for a wide range of electronic applications. Flash memory devices typically include one or more groups of one-transistor, floating gate or charge trap memory cells, that allow for high memory densities, high reliability, and low power consumption. Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, memory cells in a string of the array are coupled together in series between a source line and a data line.

Using 3D architectures for memory devices, such as NAND memory devices, can provide increased capacity over planar structures. The memory arrays for 3D structures can include memory cells stacked vertically as strings of memory cells. In selecting one or more strings for access to given memory cells, gating structures can be located at the top and bottom of these strings with memory cells storing data therebetween. The gating structures can include a select gate transistor with its drain coupled to a data line, such as a bitline, at one end of a string and a select gate transistor with its source coupled to a source line at the other end of the string. A select gate transistor with its drain coupled to a data line is referred to as a drain-side select gate (SGD TRANSISTOR) transistor. A select gate transistor with its source coupled to a source line is referred to as a source-side select gate (SGS) transistor.

Both NOR and NAND flash architecture semiconductor memory arrays of flash memory devices are accessed through decoders that activate specific memory cells by selecting an access line (WL) coupled to gates of specific memory cells. In a NOR architecture semiconductor memory array, once activated, the selected memory cells place their data values on data lines (DLs), causing different currents to flow depending on the state at which a particular cell is programmed. In a NAND architecture semiconductor memory array, a relatively high bias voltage is applied to a SGD TRANSISTOR line. Access lines coupled to the gates of the unselected memory cells of each group are driven at a specified pass voltage (Vpass) to operate the unselected memory cells of each group as pass transistors, for example, to pass current in a manner unrestricted by their stored data values. Current then flows in the line between the source line and the data line through each series-coupled group, restricted only by the selected memory cells of each group, placing current-encoded data values of selected memory cells on the data lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data. Flash memory cells can also represent more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC has been referred to as a memory cell that can store two bits of data per cell (e.g., one of four programmed states). MLC is used herein in its broader context, to refer to any memory cell(s) that can store more than one bit of data per cell (i.e., that can represent more than two programmed states). Herein, a memory cell that can store two bits of data per cell (e.g., one of four programmed states) is referred to as a dual-level cell (DLC). A triple-level cell (TLC) refers to a memory cell that can store three bits of data per cell (e.g., one of eight programmed states). A quad-level cell (QLC) can store four bits of data per cell, and a penta-level cell (PLC) can store five bits of data per cell. In a string of memory cells in a 3D memory device such as a 3D NAND memory, access to the string to operate on a memory cell in the string can be controlled by a gating selector device, such as a SGD transistor, which is in series with the memory cells of the string. The string of memory cells can be realized by a vertical pillar having memory cells arranged in tiers along the vertical pillar.

In various embodiments, dual channels along pillars in a memory array of a memory device can be structured for memory cells along the pillar. The dual-channel pillars can be arranged along rows in the memory array of the memory device. The memory device can be a NAND memory device. The dual channels along each pillar can be implemented with a SGD transistor substantially interior to the pillar. In a NAND memory device, this dual-channel per pillar architecture with a pillar interior SGD transistor can increase the density of NAND memory cells. In this design, the gate of the SGD transistor can be strategically positioned within the center of the pillar, as opposed to the traditional exterior placement, allowing for a more compact architecture. The interior SGD transistor, combined with interconnects, enables the selection of a reduced number of channel strings, thereby maintaining a standard number of data lines, such as four data lines per sub-block over pillar pairs. This configuration not only optimizes the use of chip area per channel but also supports higher density and nominal bits per sub-block.

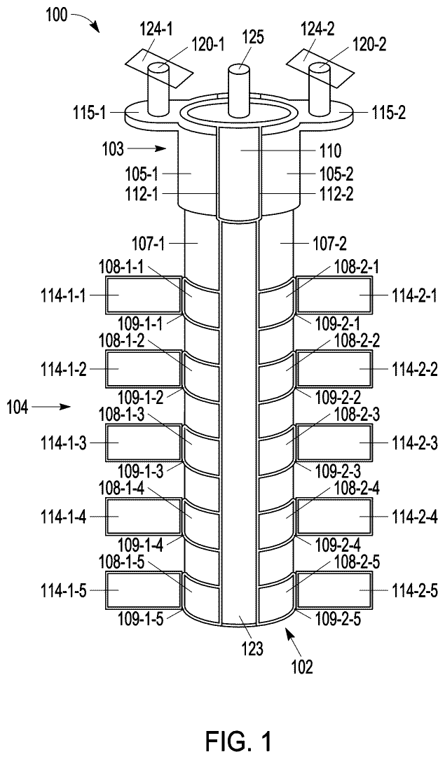

FIG. 1 is a representation a pillar arrangement in a memory device 100 having a SGD transistor 103 in a pillar 102 with memory cells arranged in tiers along pillar 102. The memory cells can be structured as a deck 104 of memory cells. Pillar 102 provides a vertical string of memory cells. SGD transistor 103 can be substantially structured in pillar 102 at a level above the memory cells. Deck 104 can be structured as one deck of multiple decks of tiers of memory cells. The pillar arrangement can be implemented for multiple pillars in multiple rows of a memory array of memory device 100. SGD transistor 103 can have a gate 110 and two channel structures 105-1 and 105-2. Gate 110 can include n+ polysilicon. Gate 110 can be separated from channel structure 105-1 by a vertical segment of a gate dielectric 112-1 and from channel structure 105-2 by a vertical segment of a gate dielectric 112-2. Vertical segments of gate dielectrics 112-1 and 112-2 can be coupled together. Vertical segments of gate dielectrics 112-1 and 112-2 can connect to each other by horizontal segments of gate dielectrics 112-1 and 112-2 that are on a dielectric fill 123 of pillar 102 and contact gate 110.

SGD transistor 103 can include a drain 115-1 coupled to channel structure 105-1 and a drain 115-2 coupled to channel structure 105-2. Drain 115-1 can have a drain contact 120-1 coupled to a BL 124-1 and drain 115-2 can have a drain contact 120-2 coupled to a BL 124-2. Gate 110 can be coupled to a SGD contact 125 that is coupled to select circuitry of memory device 100. Gate 110 can be located directly above dielectric fill 123 of pillar 102. Gate 110 can be located within virtual vertical boundaries of dielectric fill 123 extending vertically from dielectric fill 123.

SGD transistor 103 can be situated substantially within virtual vertical extensions of the boundaries of pillar 102, where portions of SGD transistor 103 can extend laterally (horizontally) out from the vertical extensions. SGD transistor 103 can be substantially centered in pillar 102. SGD contact 125 can be substantially centered with respect to the center of pillar 102. SGD contact 125 can include titanium, titanium nitride, tungsten, or other appropriate conductive material. Channel structure 105-1 of SGD transistor 103 can be coupled to or be structured as an extension of a pillar channel structure 107-1 for pillar 102, where pillar channel structure 107-1 is vertically on and contacting a dielectric such as dielectric fill 123 of pillar 102. Channel structure 105-2 of SGD transistor 103 can be coupled to or be structured as an extension of a pillar channel structure 107-2 for pillar 102 that is vertically on and contacting a dielectric such as dielectric fill 123 of pillar 102. Dielectric fill 123 separates pillar channel structure 107-2 from the pillar channel structure 107-2. A source for SGD transistor 103 can be coupled to the end of pillar channel structure 107-1 and to the end of pillar channel structure 107-2, distal from channel structures 105-1 and 105-2 of SGD transistor 103. The arrangement of pillar channel structure 107-1 and pillar channel structure 107-2 as dual channels allows for two different memory cells to be structured on a tier along pillar 102 such that a single memory cell does not encircle pillar 102. Alternatively, a SGD transistor can be formed interior to a vertical pillar having memory cells at tiers along the vertical pillar, where at each tier the memory cell encircles the pillar.

Each memory cell along pillar 102 on the same side as pillar channel structure 107-1 from dielectric fill 123 can be arranged in a tier along pillar 102 and can include a storage node separated from pillar channel structure 107-1 by a tunnel dielectric. In a first tier, a memory cell includes a storage node 108-1-1 separated from pillar channel structure 107-1 by a tunnel dielectric 109-1-1 and coupled to a WL 114-1-1. In a second tier, a memory cell includes a storage node 108-1-2 separated from pillar channel structure 107-1 by a tunnel dielectric 109-1-2 and coupled to a WL 114-1-2. In a third tier, a memory cell includes a storage node 108-1-3 separated from pillar channel structure 107-1 by a tunnel dielectric 109-1-3 and coupled to a WL 114-1-3. In a fourth tier, a memory cell includes a storage node 108-1-4 separated from pillar channel structure 107-1 by a tunnel dielectric 109-1-4 and coupled to a WL 114-1-4. In a fifth tier, a memory cell includes a storage node 108-1-5 separated from pillar channel structure 107-1 by a tunnel dielectric 109-1-5 and coupled to a WL 114-1-5. Pillar channel structure 107-1 can be structured as a continuous structure that provides a channel structure for each of the memory cells of tiers 1-5 on the same side of pillar 102 as pillar channel structure 107-1. Tunnel dielectrics 109-1-1 to 109-1-5 can be, but is not limited to, an arrangement having a structure as a single dielectric that runs continuously along pillar 102 and is vertically on and contacting pillar channel structure 107-1.

Each memory cell along pillar 102 on the same side as pillar channel structure 107-2 from dielectric fill 123 is arranged in a tier along pillar 102 and includes a storage node separated from pillar channel structure 107-2 by a tunnel dielectric. In the first tier, a memory cell includes a storage node 108-2-1 separated from pillar channel structure 107-2 by a tunnel dielectric 109-2-1 and coupled to a WL 114-2-1. In the second tier, a memory cell includes a storage node 108-2-2 separated from pillar channel structure 107-2 by a tunnel dielectric 109-2-2 and coupled to a WL 114-2-2. In the third tier, a memory cell includes a storage node 108-2-3 separated from pillar channel structure 107-2 by a tunnel dielectric 109-2-3 and coupled to a WL 114-2-3. In the fourth tier, a memory cell includes a storage node 108-2-4 separated from pillar channel structure 107-2 by a tunnel dielectric 109-2-4 and coupled to a WL 114-2-4. In the fifth tier, a memory cell includes a storage node 108-2-5 separated from pillar channel structure 107-2 by a tunnel dielectric 109-2-5 and coupled to a WL 114-2-5. Pillar channel structure 107-2 can be structured as a continuous structure that provides a channel structure for each of the memory cells of tiers 1-5 on the same side of pillar 102 as pillar channel structure 107-2. Tunnel dielectrics 109-2-1 to 109-2-5 can be, but is not limited to, an arrangement having a structure as a single dielectric that runs continuously along pillar 102 and is vertically on and contacting pillar channel structure 107-2.

For the memory cells of the first tier, WL 114-1-1 and WL 114-2-1 can be structured as a common access line. For the memory cells of the second tier, WL 114-1-2 and WL 114-2-2 can be structured as a common access line. For the memory cells of the third tier, WL 114-1-3 and WL 114-2-3 can be structured as a common access line. For the memory cells of the fourth tier, WL 114-1-4 and WL 114-2-4 can be structured as a common access line. For the memory cells of the fifth tier, WL 114-1-5 and WL 114-2-5 can be structured as a common access line. Though five tiers are shown in deck 104 of FIG. 1, deck 104 can include substantially more than five tiers. Alternatively, WLs to a tier of a given pillar, such as pillar 102, can be structurally, electrically non-connected at the pillar.

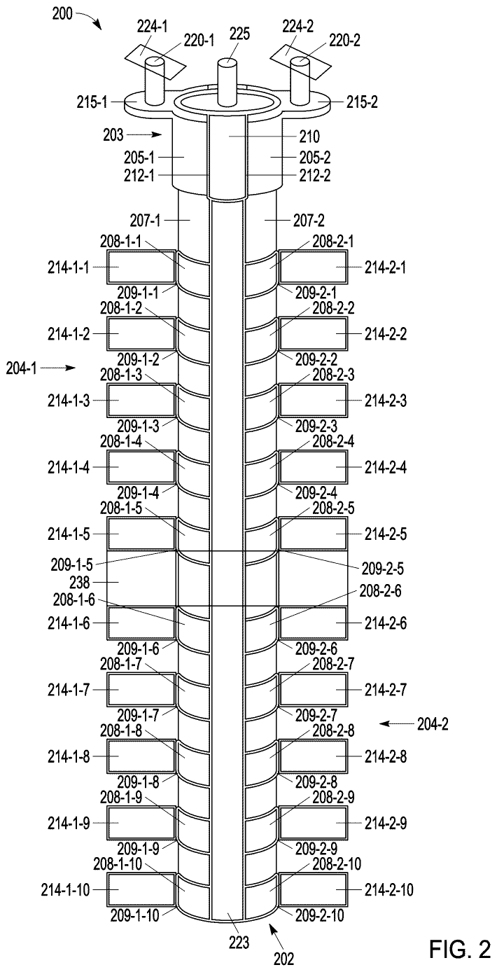

FIG. 2 is a representation a pillar arrangement in a memory device 200 having a SGD transistor 203 in a pillar 202 with memory cells arranged in tiers along pillar 202 structured as multiple decks of memory cells. Memory device 200 can include deck 204-1 and deck 204-2 separated by a dielectric region 238, created to form deck 204-1 on deck 204-2. Decks 204-1 and deck 204-2 can be structured similar to deck 104 of FIG. 1. Though two decks of memory are shown for memory cells along pillar 202, more than two decks of memory cells can be structured along pillar 202. Pillar 202 can be structured as segments, with one segment for each deck. A segment of pillar 202 can be stacked on another segment of pillar 202. The segments can be aligned such that the center of one segment is aligned with the segment of another segment. Alternatively, segments can be stacked such that the centers of decks are shifted from each other. The shift can be a small offset such that the stacking of the decks are substantially centered for fabrication.

SGD transistor 203 can have a gate 210 and two channel structures 205-1 and 205-2. Gate 210 can be separated from channel structure 205-1 by a vertical segment of a gate dielectric 212-1 and from channel structure 205-2 by a vertical segment of a gate dielectric 212-2. Vertical segments of gate dielectrics 212-1 and 212-2 can be coupled together. Vertical segments of gate dielectrics 212-1 and 212-2 can be connected to each other by horizontal segments of gate dielectric 212-1 and gate dielectric 212-2 that are on a dielectric fill 223 of pillar 202. SGD transistor 203 can include a drain 215-1 coupled to channel structure 205-1 and a drain 215-2 coupled to channel structure 205-2. Drain 215-1 can have a drain contact 220-1 coupled to a BL 224-1 and drain 215-2 can have a drain contact 220-2 coupled to a BL 224-2. Gate 210 can be coupled to a SGD contact 225 that is coupled to select circuitry of memory device 200.

SGD transistor 203 can be situated substantially within virtual vertical extensions of the boundaries of pillar 202, where portions of SGD transistor 203 can extend laterally (horizontally) out from the vertical extensions. SGD transistor 203 can be substantially centered in pillar 202. Gate contact 225 can be substantially centered with respect to the center of deck 204-1 of pillar 202. Channel structure 205-1 of SGD transistor 203 can be coupled to or be structured as an extension of a pillar channel structure 207-1 for pillar 202 that is vertically on and contacting dielectric fill 223 of pillar 202. Channel structure 205-2 of SGD transistor 203 can be coupled to or be structured as an extension of a pillar channel structure 207-2 for pillar 202 that is vertically on and contacting dielectric fill 223 of pillar 202. Dielectric fill 223 separates pillar channel structure 207-2 from the pillar channel structure 207-2. A source for SGD transistor 203 can be coupled to the end of pillar channel structure 207-1 and to the end end of pillar channel structure 207-2, distal from channel structures 205-1 and 205-2 of SGD transistor 203.

Each memory cell along pillar 202 on the same side as pillar channel structure 207-1 from dielectric fill 223 is arranged in a tier along pillar 202 and includes a storage node separated from pillar channel structure 207-1 by a tunnel dielectric. For each tier, i=1 . . . 10, a storage node 208-1-i can be separated from pillar channel structure 207-1 by a tunnel dielectric 209-1-i and coupled to a WL 214-1-i. Each memory cell along pillar 202 on the same side as pillar channel structure 207-2 from dielectric fill 223 is arranged in a tier along pillar 202 and includes a storage node separated from pillar channel structure 207-1 by a tunnel dielectric. For each tier, i=1 . . . 10, a storage node 208-2-i can be separated from pillar channel structure 207-2 by a tunnel dielectric 209-2-i and coupled to WL 214-2-i. For each tier i, WL 214-1-i and WL 214-2-i can be structured as a common access line. Alternatively, WLs to a tier of a given pillar, such as pillar 202, can be structurally, electrically non-connected at the given pillar. Though five tiers are shown in deck 204-1 of FIG. 2 and five tiers are shown in deck 204-2 of FIG. 2, deck 204-1 can include substantially more than five tiers and deck 204-2 can include substantially more than five tiers.

The dual channels associated with pillars along which memory cells can be arranged, as structured in memory device 100 of FIG. 1 or memory device 200 of FIG. 2, can provide for increased density of memory cells and channels as compared to conventional memory devices of the same type. Gates 110 and 210 of SGD transistors 103 and 203 can be centrally located with respect to the center of pillars 102 and 202, respectively. In conventional NAND memory devices, SGD transistors are located outside the pillars, taking up more chip area. Dual channels per pillar can provide for segmentation of storage material at a tier along the pillar. For a pillar pair, four data lines per sub-block can be implemented using the SGD transistor formed inside the pillars with interconnects.

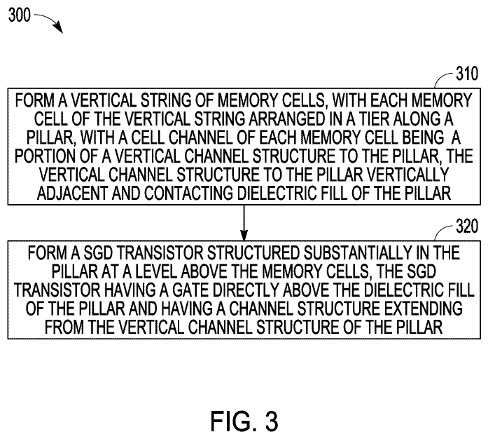

FIG. 3 is a flow diagram of features of an example method 300 of forming a memory device. Features of method 300 can be implemented to form memory device 100 of FIG. 1, memory device 200 of FIG. 2, or other memory device having a SGD transistor structured substantially in the pillar. At 310, a vertical string of memory cells is formed. Each memory cell of the vertical string is arranged in a tier along a pillar, with a cell channel of each memory cell being a portion of a vertical channel structure to the pillar. The vertical channel structure to the pillar is vertically adjacent and contacting dielectric fill of the pillar.

At 320, a SGD transistor is formed structured substantially in the pillar at a level above the memory cells. The SGD transistor has a gate directly above the dielectric fill of the pillar along with a channel structure extending from the vertical channel structure of the pillar. The channel structure of the SGD transistor can be structured with a portion of the SGD transistor arranged laterally (horizontally) out from the vertical channel structure of the pillar.

Variations of method 300 or methods similar to method 300 can include a number of different embodiments that may be combined depending on the application of such methods or the architecture or process flow of forming a memory device for which such methods are implemented. Such methods can include performing a number of procedures in which the SGD transistor is formed structured substantially in the pillar along with other SGD transistors being formed structured substantially in other pillars. Such procedures can begin with forming a stack of materials for tiers of memory cells. Rows of pillar openings can be formed in the stack of materials and other openings can be formed in the stack of materials such that adjacent pillar openings in a row can be connected by the other openings, where the other openings are necked down in size relative to the pillar openings. Memory cells and vertical channel structures can be formed in the pillar openings. The dielectric fill can be formed in all the pillars being constructed such that the dielectric fill contacts the vertical channel structures in the respective pillar openings. Gates for the SGD transistors can be formed above the dielectric fill. The openings that connected the pillar openings can be filled with a dielectric and drain contacts can be formed between the gates and the dielectric in the openings that connected the pillar openings.

Variations of method 300 or methods similar to method 300 in which the SGD transistor is formed structured substantially in the pillar along with other SGD transistors, being formed structured substantially in other pillars, can be implemented. Multi-pillar slits can be formed at ends of the rows, where the multi-pillar slits extend in a direction generally perpendicular to the rows of pillar openings. The multi-pillar slits can be used to perform a replacement gate process to substitute gate material for material in the stack of materials at tier locations.

Variations of method 300 or methods similar to method 300 in which the SGD transistor is formed structured substantially in the pillar along with other SGD transistors, being formed structured substantially in other pillars, can be implemented. The vertical channel structures in the pillar openings can be formed as first vertical channel structures and second vertical channel structures. The drain contacts of the SGD transistors of the pillars can be formed by forming two drain contacts per pillar, where one of the two drain contacts is coupled to the first vertical channel structure and a second one of the two drain contacts is coupled to the second vertical channel structure. Variations of method 300 or methods similar to method 300 can include the vertical channel structure to the pillar being structured continuously around the dielectric fill of the pillar forming a single channel structure in the pillar. Variations can include forming a conductive line coupling a gate in one row to a gate of another row. This conductive line can continue to gates in the adjacent rows for all rows in a selected region.

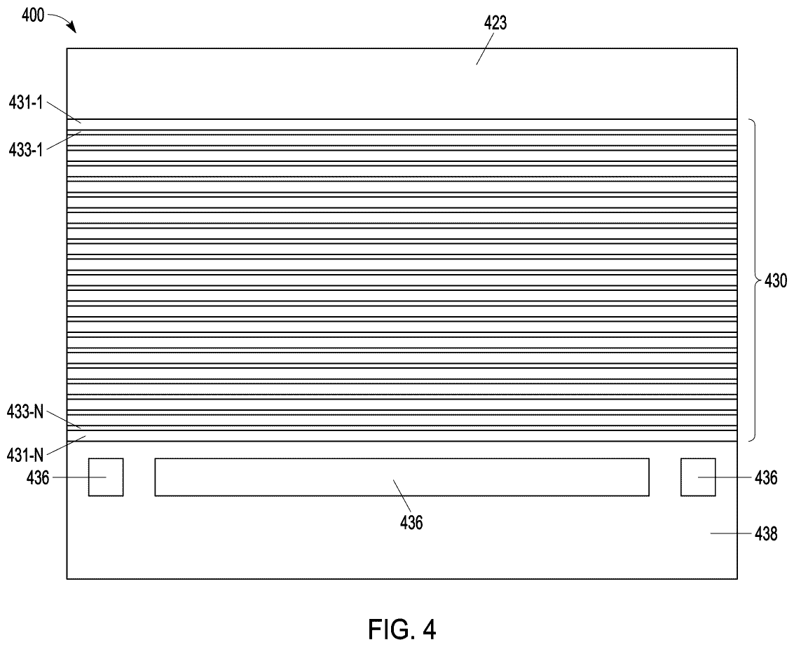

FIGS. 4-54 illustrate features of an embodiment of an example process flow of fabricating a memory device having an array of memory cells structured as an array of pillars, with memory cells arranged in tiers along the pillars and a drain-side select gate transistor in an interior to each pillar. The memory device can be a NAND memory. The features of the array of pillars and additional features are not drawn to scale in FIGS. 4-54.

FIG. 4 illustrates a cross-sectional view of a structure 400 after layers 430 of material for forming a tier stack of memory cells arranged with respect to vertical pillars has been formed. Layers 430 include nitride tiers 431-1 . . . 431-N alternating with oxide layers 433-1 . . . 433-N. Nitride tiers 431-1 . . . 431-N and oxide layers 433-1 . . . 433-N have been formed on a dielectric layer 438 that can be used for forming a common source, lateral connects, and pillar landing pads. Layer 436 has been formed as an etch stop. Though not shown, at this point in the fabrication process, a staircase structure can be formed from which access line contacts can extend vertically. A dielectric region 423 has been formed to cover the tier stack. Dielectric region 423, which can be but is not limited to an oxide, has been formed with a thickness corresponding to a thickness to form SGD transistors interior to pillars. Dielectric region 423 is structured to be etched back at a faster rate than dielectrics of the SGD transistors being formed using dielectric region 423.

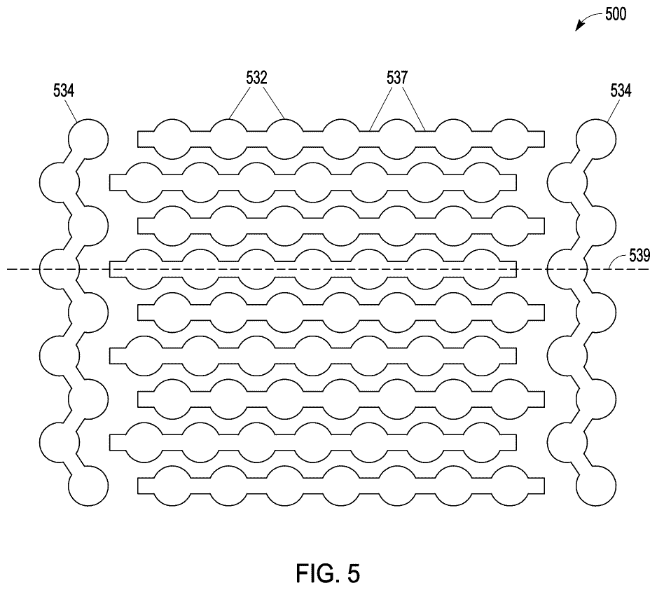

FIG. 5 illustrates top view of a pattern 500 after processing structure 400 of FIG. 4. Pattern 500 for pillars has been formed and structure 400 has been etched according to pattern 500. Pattern 500 includes rows having areas for pillars in each row and areas connecting adjacent areas for pillars in each row. The connecting areas are necked down areas from the areas for the pillars, forming each row as a daisy chain of connected pillar locations. The etching has formed pillar openings 532 and connection openings 537 from etching the necked down areas. The patterning has also included patterning and forming openings at opposite ends of the rows patterned for pillars, forming multi-pillar slits (MPSs) 534. MPSs 534 can be formed as pillar openings connected by necked down areas. Formed MPS pillars and the array pillars can typically have the same sizes. Etch stop plug material of layer 436 of structure 400 of FIG. 4 has been exhumed using pillar openings 532, connection openings 537, and MPS opening 534. A reference line 539 is shown for further discussions of the fabrication process flow of FIGS. 4-54. Processing along reference line 539 for a patterned row can also be performed simultaneously for the other patterned rows of pattern 500 in the fabrication process flow.

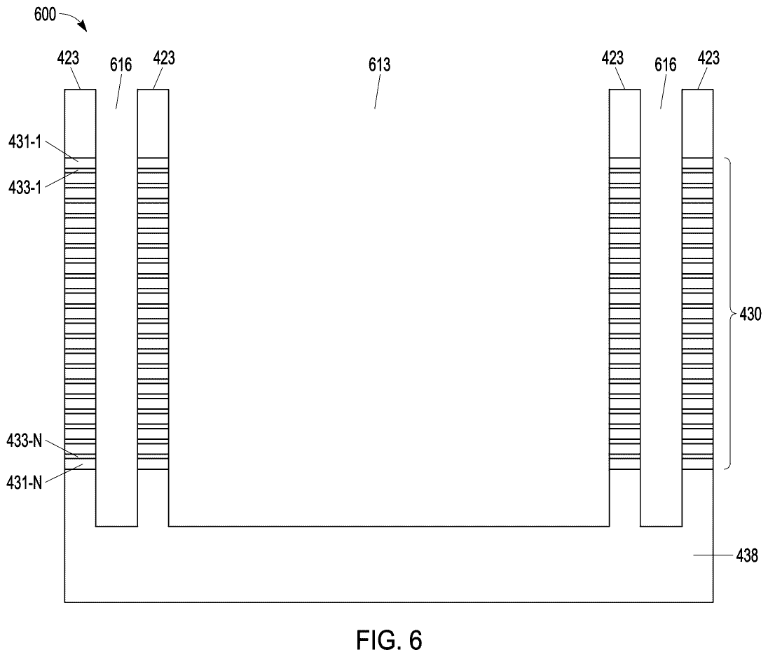

FIG. 6 illustrates a structure 600 that is a cross-sectional view along reference line 539 of FIG. 5 of the openings formed after processing structure 400 of FIG. 4 according to pattern 500 shown in FIG. 5. An opening 613 has been provided by the continuous daisy chain of pillar openings 532 and connection openings 537 along reference line 539 and MPS pillar openings 616 at the end of the row pattern along reference line 539.

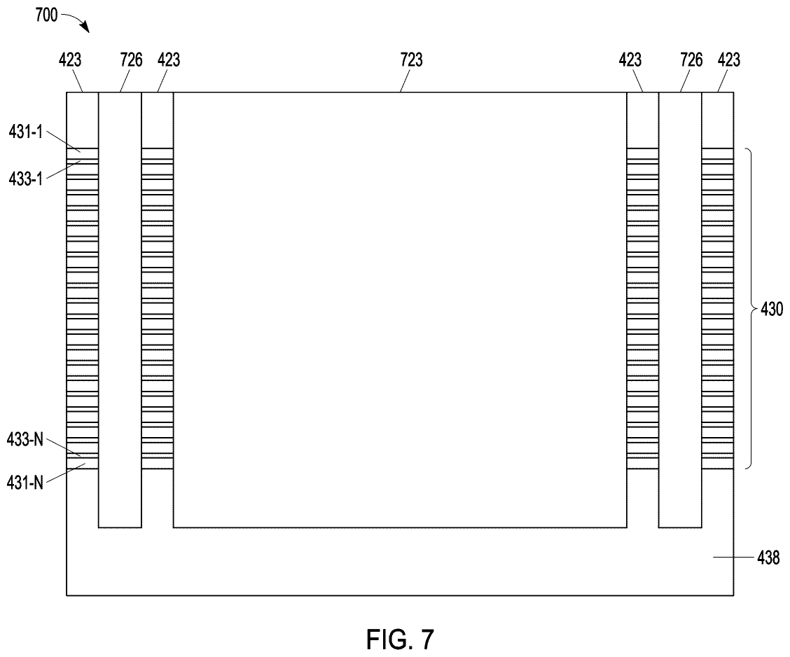

FIG. 7 is a cross-sectional view of a structure 700 along reference line 539 of FIG. 5 after further processing structure 600. A sacrificial fill 723 has been formed in the opening 613 and a sacrificial fill 726 has been formed in the openings 616. Sacrificial fill 723 and sacrificial fill 726 can be formed of the same material in a common procedure. The materials of sacrificial fill 723 and sacrificial fill 726 can be a dielectric material.

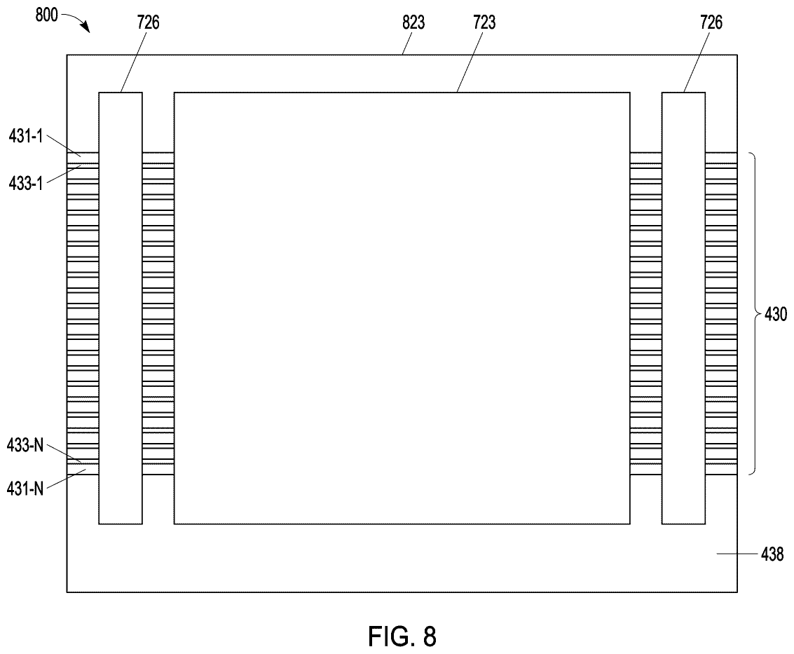

FIG. 8 is a cross-sectional view of a structure 800 along reference line 539 of FIG. 5 after further processing structure 700. The exposed surfaces of structure 700 have been covered with a dielectric material 823. The dielectric material 823 can be a dielectric oxide, such as, but not limited to, silicon oxide (SiO_{X}).

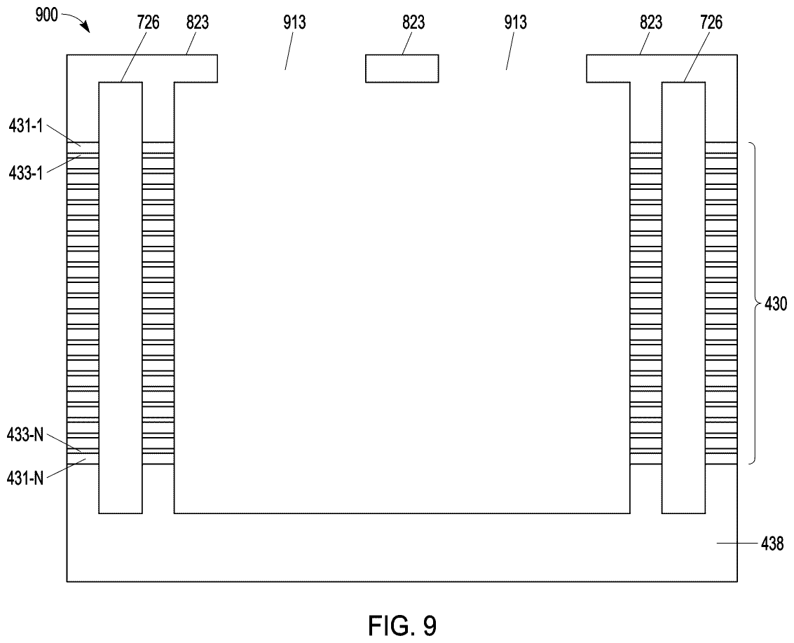

FIG. 9 is a cross-sectional view of a structure 900 along reference line 539 of FIG. 5 after further processing structure 800. For ease of presentation, processing for only two pillar openings along a chain of patterned pillar openings of FIG. 5 are shown in FIG. 9. This presentation format with respect to reference line 539 is continued throughout the discussion of the fabrication process of common structures of a pillar array for memory cells of the memory device being fabricated. Holes 913 have been etched through dielectric material 823 of structure 800 using a pattern for the memory pillars to be formed. Sacrificial fill 723 has been exhumed from the locations for the memory array pillars.

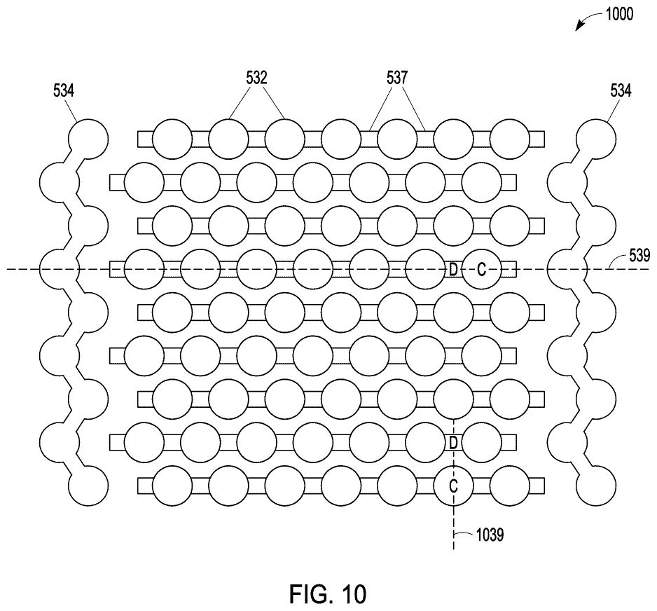

FIG. 10 illustrates a top view of a pattern 1000 showing a second reference line 1039 in addition to reference line 539 of FIG. 5. While reference line 539 is along a row of patterned row locations, reference line 1039 is in a direction across the patterned row locations. Locations C are at centers of the patterned pillar locations and locations D are at a mid-point between adjacent patterned pillar locations in the necked down regions.

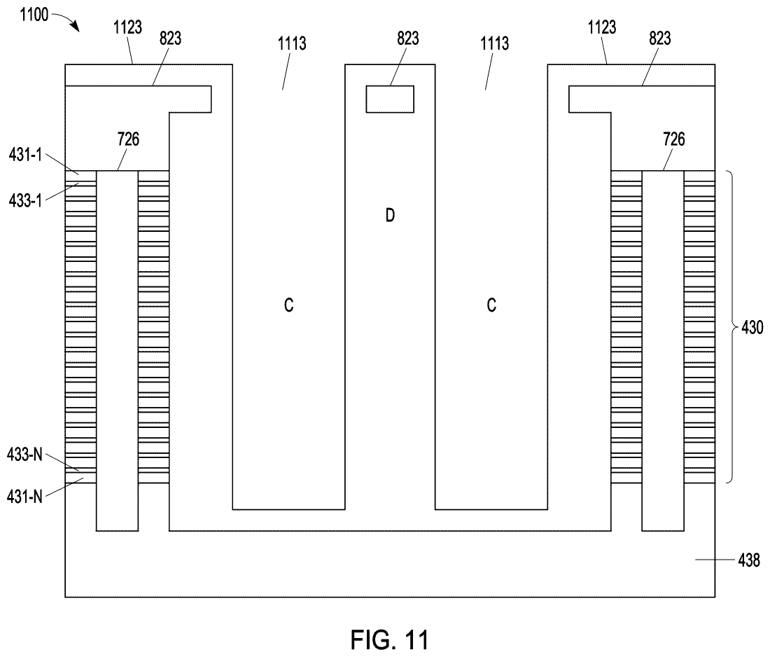

FIG. 11 is a cross-sectional view of a structure 1100 along reference line 539 of FIG. 10 after further processing structure 900 of FIG. 9. Sacrificial material 1123 has been formed to a thickness sufficient to pinch off necked down areas in daisy chained array areas along the rows of pillar locations, but leaving voids 1113. The centers C of pillar positions are in voids 1113 and locations D are in sacrificial material 1123 between voids 1113. The formation of sacrificial material 1123 can be accomplished with an appropriate deposition procedure. Sacrificial material 1123 can be, but is not limited to, polysilicon.

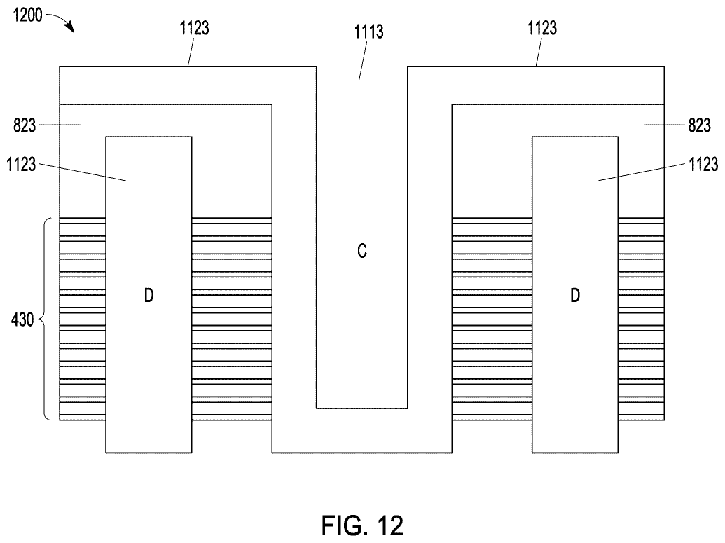

FIG. 12 is a cross-sectional view 1200 along reference line 1039 of FIG. 10 of structure 1100, which is a view of structure 1100 in a direction substantially perpendicular to the view of FIG. 11, after further processing structure 900 of FIG. 9. Cross-sectional view 1200 shows the relationship of a void 1113 having a center C and location D in sacrificial material 1123 across the rows for the memory array.

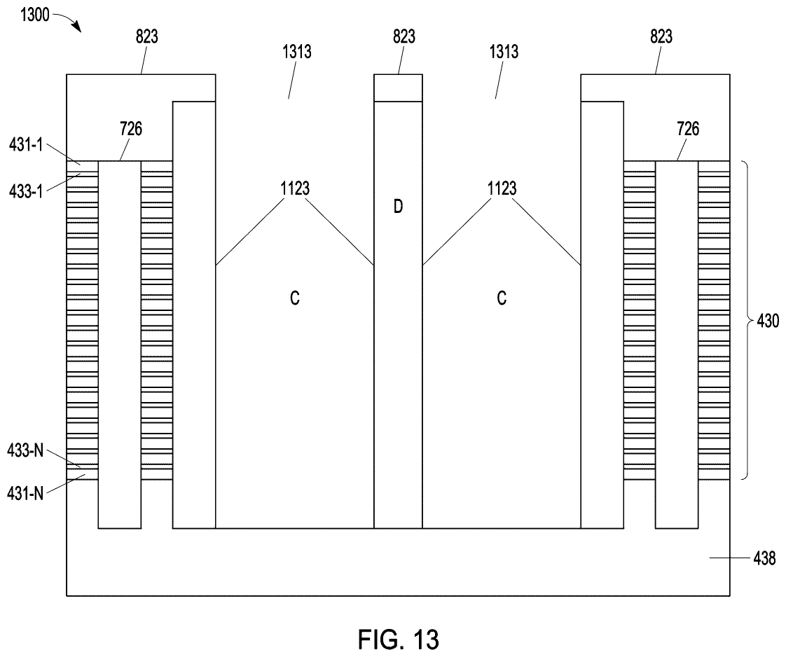

FIG. 13 is a cross-sectional view of a structure 1300 along reference line 539 of FIG. 10 after further processing structure 1100 of FIG. 11. Sacrificial material 1123 has been selectively etched from the sides of voids 1113 of the pillar daisy chains, leaving openings 1313. Sacrificial material 1123 has been left in the necked down areas of the pillar daisy chains. The centers C of pillar positions are in openings 1313 and locations D remain in sacrificial material 1123 between openings 1313.

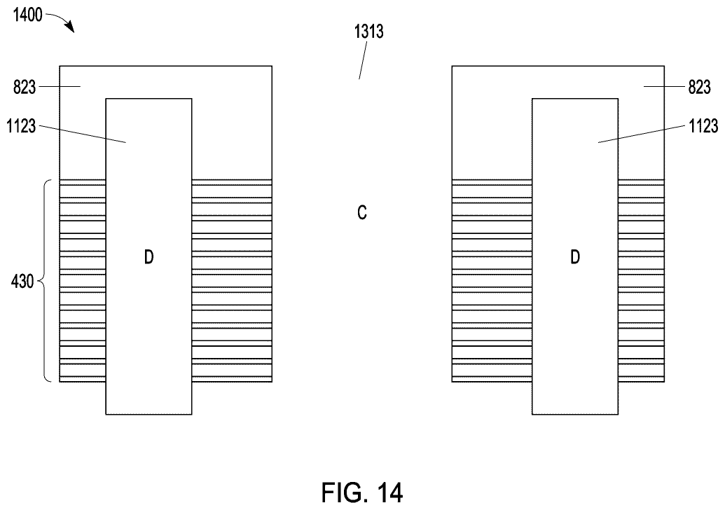

FIG. 14 is a cross-sectional view 1400 along reference line 1039 of FIG. 10 of structure 1300, which is a view of structure 1300 in a direction substantially perpendicular to the view of FIG. 13, after further processing structure 1100 of FIG. 11. Cross-sectional view 1400 shows the relationship of openings 1313 having a center C and location D in sacrificial material 1123 across the rows for the memory array.

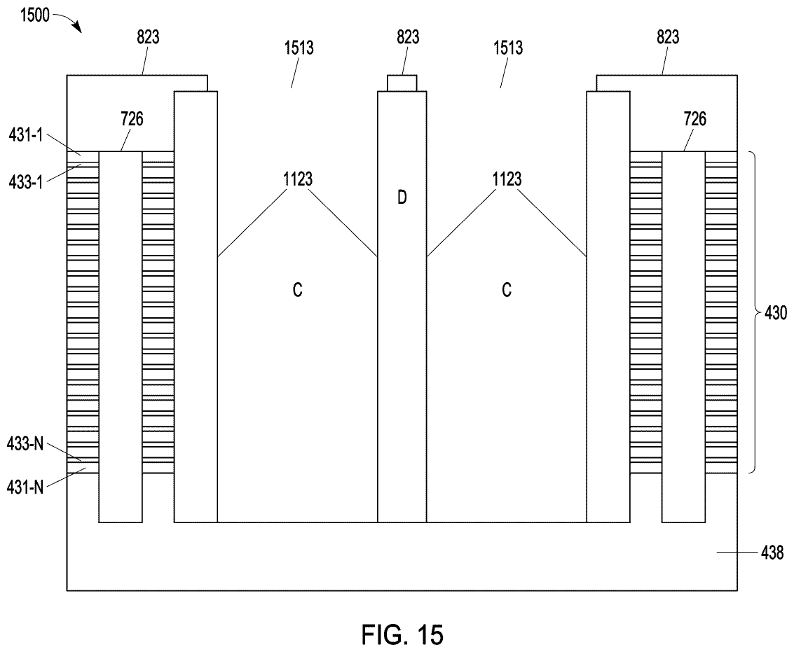

FIG. 15 is a cross-sectional view of a structure 1500 along reference line 539 of FIG. 10 after further processing structure 1300 of FIG. 13. Dielectric material 823 is selectively etched at an area for the SGD transistor of the stack back in relation to layers 430, forming openings 1513 from opening 1313 of structure 1300. The selective etch is attainted using material for dielectric material 823 that has a higher etch rate of the material of layers 430 and sacrificial material 1123. The centers C of pillar positions are in openings 1513 and locations D remain in sacrificial material 1123 between openings 1513.

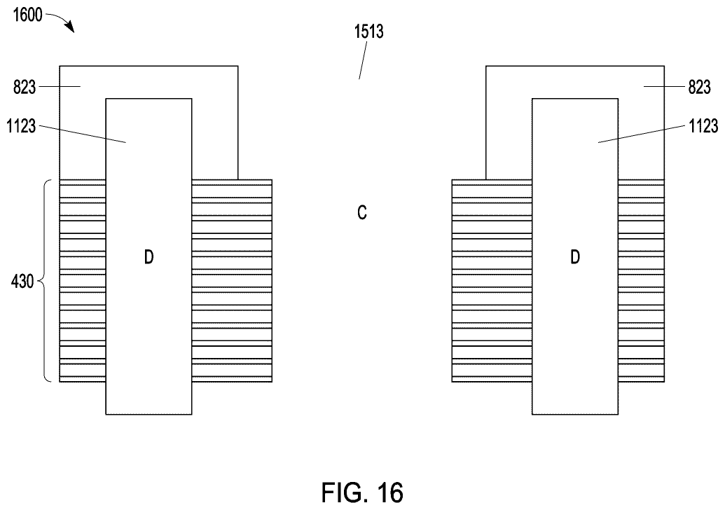

FIG. 16 is a cross-sectional view 1600 along reference line 1039 of FIG. 10, which is a view of structure 1500 in a direction substantially perpendicular to the view of FIG. 15, after further processing structure 1300 of FIG. 13. Cross-sectional view 1600 shows the relationship of opening 1513 having a center C and location D in sacrificial material 1123. Opening 1513 provides an area for a SGD transistor interior to a pillar, being formed, centered with respect to layers 430 of the tier stack, with the SGD transistor area having a portion that extends horizontally out from virtual extensions of the pillar, being formed, relative to the tier stack.

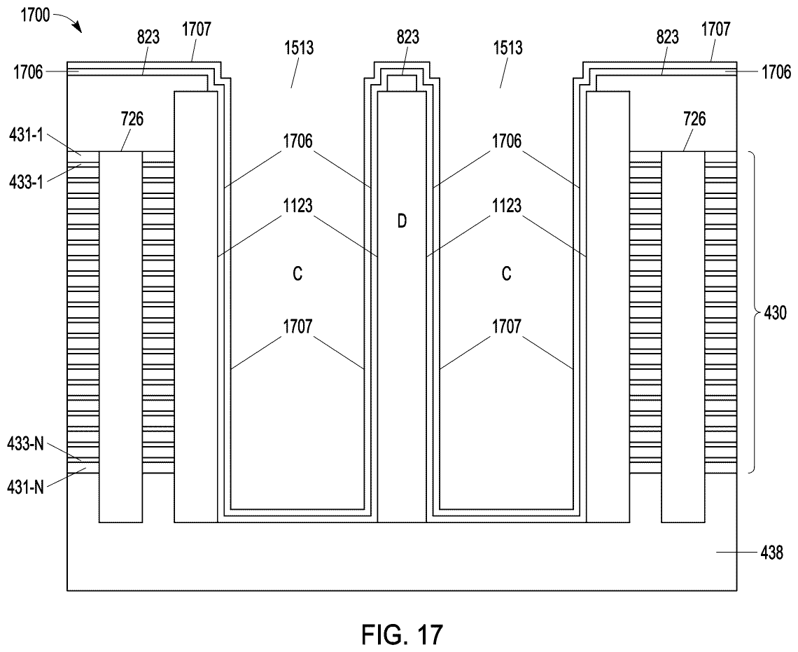

FIG. 17 is a cross-sectional view of a structure 1700 along reference line 539 of FIG. 10 after further processing structure 1500 of FIG. 15. Material 1706 for memory cells and material 1707 for channels of the memory cells has been formed. The memory cells in material 1706 can be formed as memory cells having a floating gate structure, segmented storage nitride cell structure, or a continuous storage nitride structure. Material 1706 for memory cells can include regions for tunnel dielectrics, charge storage regions, blocking dielectric region to separate the charge storage regions from gates to be formed, and an optional dielectric region between the blocking dielectric region and the gates to be formed. The centers C of pillar positions are in openings 1513 and locations D remain in sacrificial material 1123 between openings 1513.

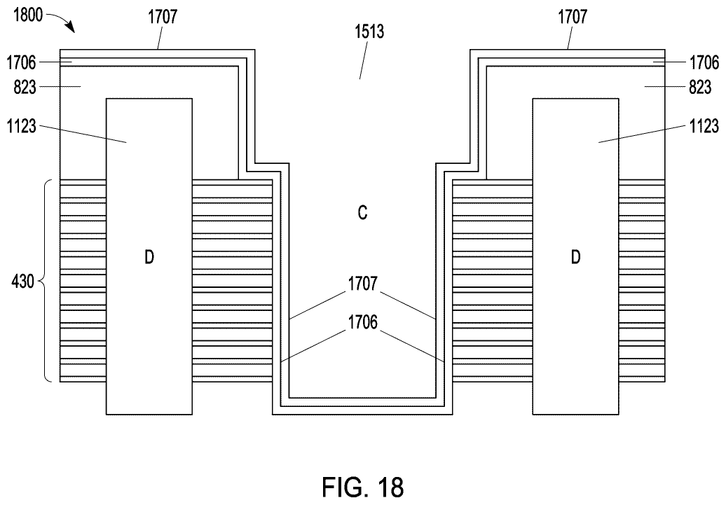

FIG. 18 is a cross-sectional view 1800 along reference line 1039 of FIG. 10, which is a view of structure 1700 in a direction substantially perpendicular to the view of FIG. 17, after further processing structure 1500 of FIG. 15. Cross-sectional view 1800 shows the relationship of opening 1513 having a center C and material 1706 for memory cells and material 1707 for channels of the memory cells, along with location D in sacrificial material 1123 across the rows for the memory array.

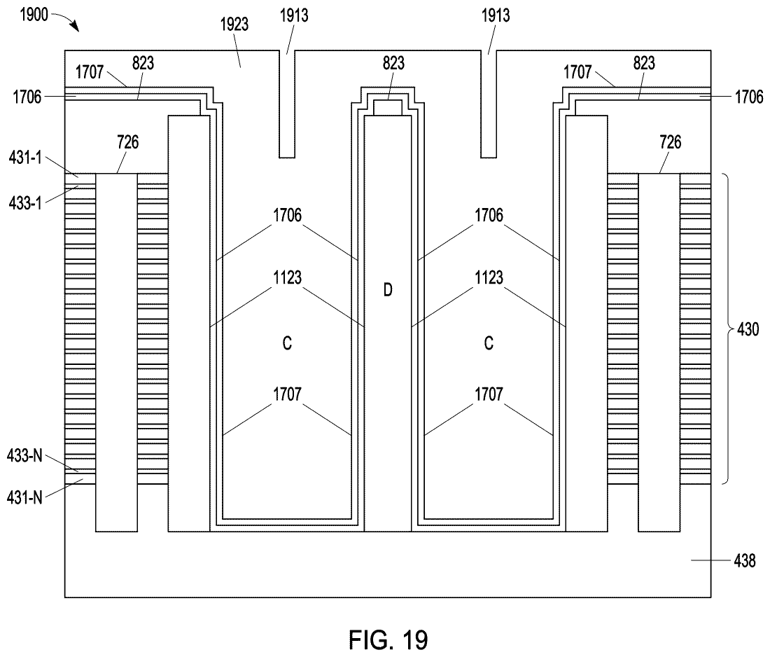

In an alternative process flow, material 1706 for memory cells and material 1707 for channels of the memory cells can be formed in the daisy chained array structures of pillar openings 532 and necked down connection openings 537 prior to forming sacrificial material 1123 in the formation of structure 1100 of FIG. 11. Cell films and polysilicon for channels can be deposited on the walls of openings 532 and necked down connection openings 537 formed in layers 430 of material for forming a tier stack of memory cells. The etchback of sacrificial material 1123 in the pillar positions, having center C, is continued in this alternative process flow with sacrificial material 1123 remaining in locations D until later in the process flow. With the polysilicon channels formed for the memory cells, sacrificial material 1123 should be selectively etched in relation to the cell polysilicon channels. In the alternative process flow, carbon, aluminum oxide (AlO_{X}), or a metal, which is properly isolated from the polysilicon channels such that the metal does not form a silicide or otherwise contaminate the polysilicon channels, can be used for sacrificial material 1123. The alternative process flow can continue with the formation of structure 1900 as illustrated in FIG. 19 and subsequent processing with procedures taken for selective etching in later processing.

FIG. 19 is a cross-sectional view of a structure 1900 along reference line 539 of FIG. 10 after further processing structure 1700 of FIG. 17. A dielectric 1923 has been formed on exposed surfaces of structure 1700, including filling openings 1513 of structure 1700. Dielectric 1923 can be formed in openings 1513 sufficiently to fill openings 1513 below the area for the SGD transistor, leaving keyholes 1913 in the area for the SGD transistor area to control subsequent etching. Dielectric 1923 can be, but is not limited to, an oxide. Dielectric 1923 provides material for pillar fill that defines a pillar at a pillar location. The centers C of pillar positions are in dielectric 1923 and locations D remain in sacrificial material 1123 between dielectric 1923 of adjacent pillar locations.

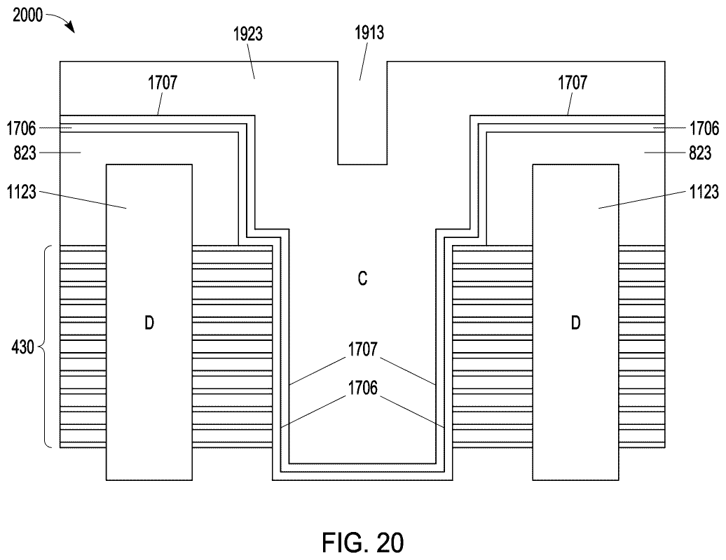

FIG. 20 is a cross-sectional view 2000 along reference line 1039 of FIG. 10, which is a view of structure 1900 in a direction substantially perpendicular to the view of FIG. 19, after further processing structure 1700 of FIG. 17. Cross-sectional view 2000 shows the relationship of dielectric 1923 having center C and location D in sacrificial material 1123 across the rows for the memory array.

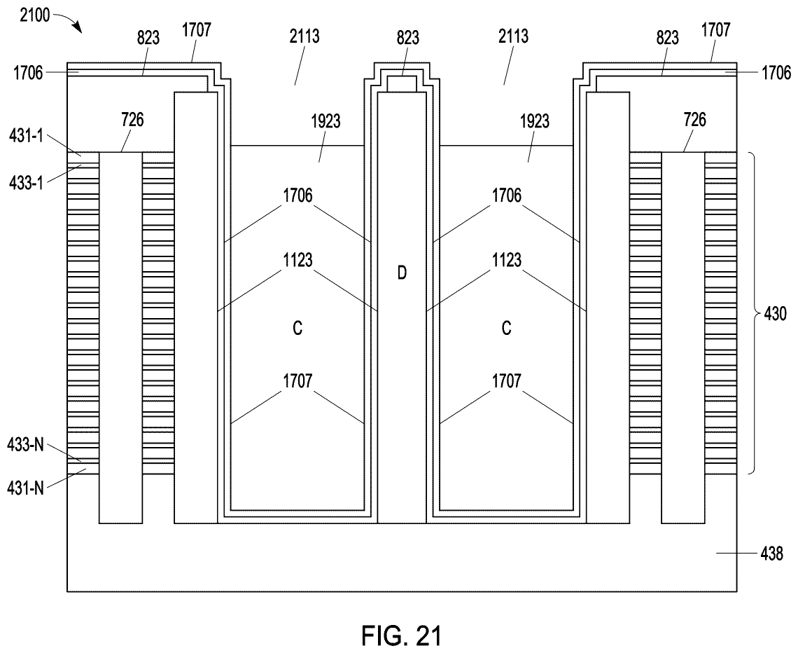

FIG. 21 is a cross-sectional view of a structure 2100 along reference line 539 of FIG. 10 after further processing structure 1900 of FIG. 19. Dielectric 1923 has been isotropically etched back exploiting keyholes 1913 to control depth of formation of recess openings 2113 of dielectric 1923. The isotropic etch can be a wet etch or a vapor etch.

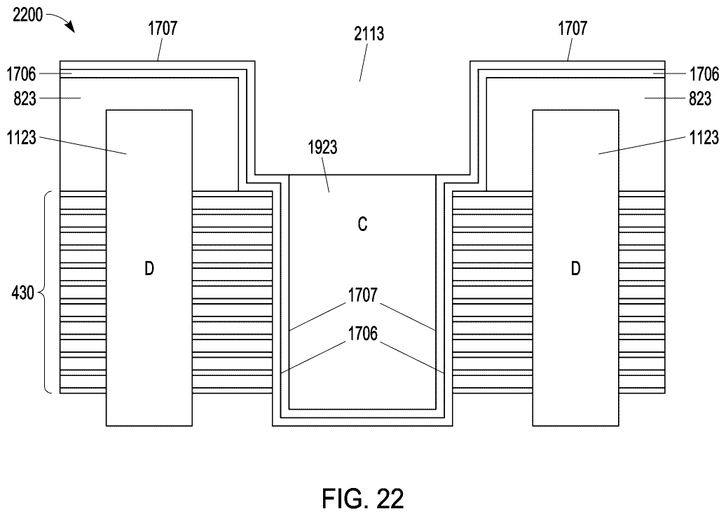

FIG. 22 is a cross-sectional view 2200 along reference line 1039 of FIG. 10, which is a view of structure 2100 in a direction substantially perpendicular to the view of FIG. 21, after further processing structure 1900 of FIG. 19. Cross-sectional view 2200 shows the relationship of recess opening 2113 above dielectric 1923 having center C and location D in sacrificial material 1123 across the rows for the memory array.

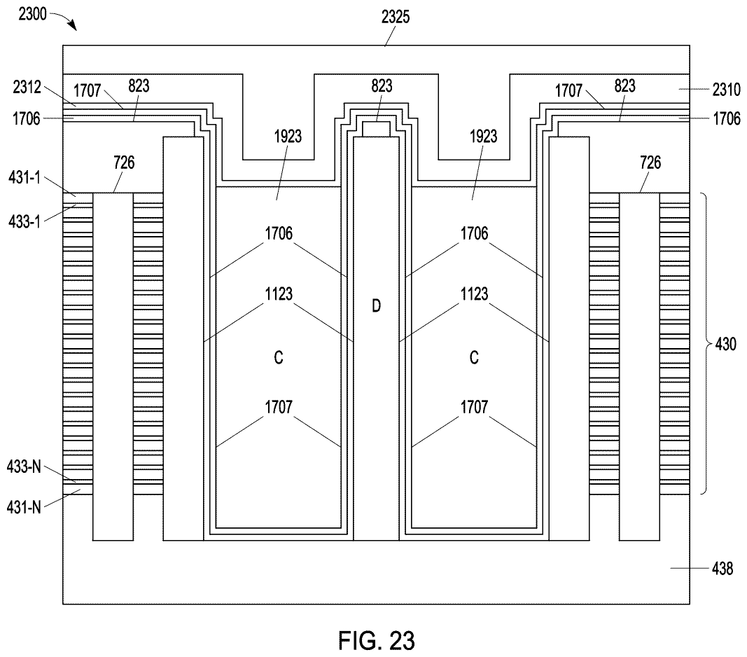

FIG. 23 is a cross-sectional view of a structure 2300 along reference line 539 of FIG. 10 after further processing structure 2100 of FIG. 21. Material 2312 for a gate dielectric has been formed on exposed structures of structure 2100. Material 2312 for a gate dielectric can be a dielectric oxide, a high-k dielectric, or a combination thereof. Material 2312 for a gate dielectric can be formed using a deposition procedure appropriate for the composition and thickness of material 2312. A high-k dielectric is a dielectric having a dielectric constant greater than the dielectric constant of silicon dioxide. Polysilicon 2310 has been formed on material 2312. Polysilicon 2310 can be doped N+. Polysilicon 2310 can be formed using an appropriate deposition procedure. A metal 2325 has been formed on polysilicon 2310. Metal 2325 can be titanium, titanium nitride, tungsten, combination of titanium, titanium nitride, and tungsten, or other metal having conductive properties to meet the specification of the memory device being formed. Metal 2325 can be formed by a metal deposition procedure appropriate for the composition and thickness for metal 2325 at this point in the process flow. Material 1707 for channels of the memory cells adjacent and vertically along material 2312 for a gate dielectric will form channel structures for SGD transistors substantially interior to the pillar configuration being formed.

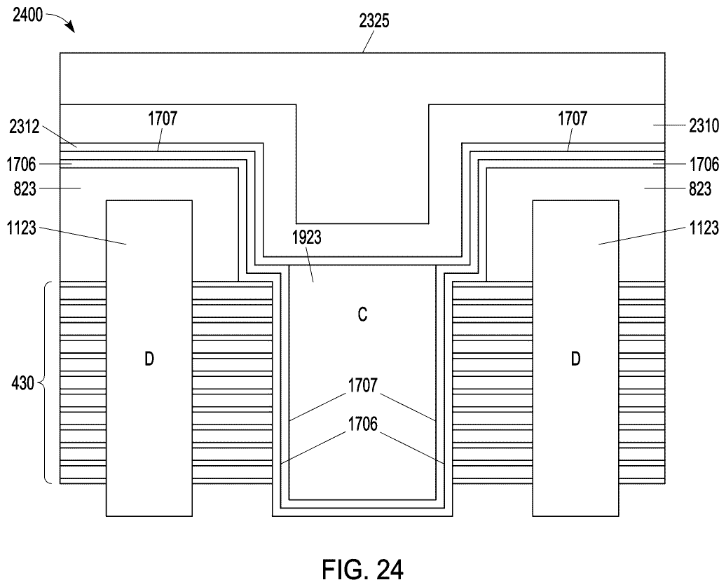

FIG. 24 is a cross-sectional view 2400 along reference line 1039 of FIG. 10, which is a view of structure 2300 in a direction substantially perpendicular to the view of FIG. 23, after further processing structure 2100 of FIG. 21. Cross-sectional view 2400 shows the relationship of the combination of material 2312 for a gate dielectric, polysilicon 2310, and metal 2325 directly above dielectric 1923 having center C and location D in sacrificial material 1123 across the rows for the memory array.

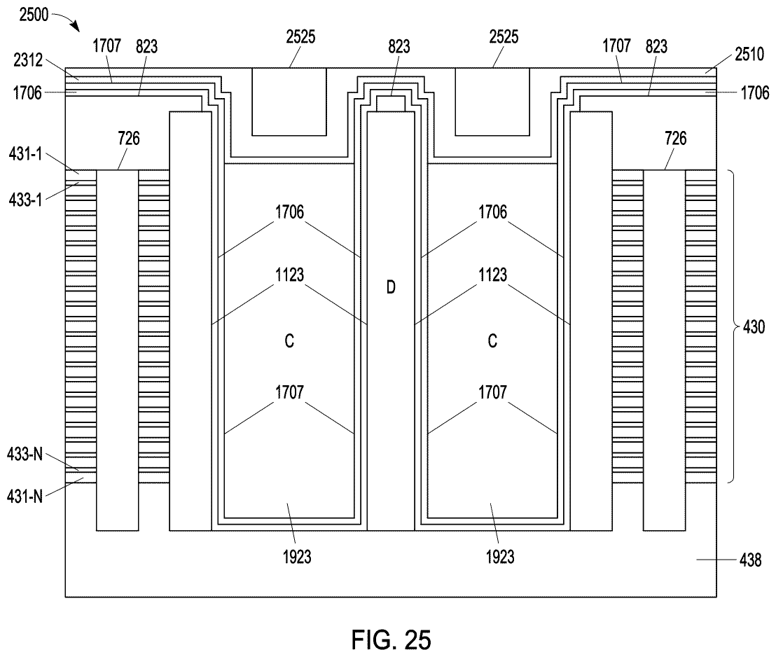

FIG. 25 is a cross-sectional view of a structure 2500 along reference line 539 of FIG. 10 after further processing structure 2300 of FIG. 23. A chemical mechanical polishing (CMP) procedure has been applied to the exposed surface of metal 2325 forming metal 2525, stopping in polysilicon 2310, reducing polysilicon 2310 to form polysilicon 2510.

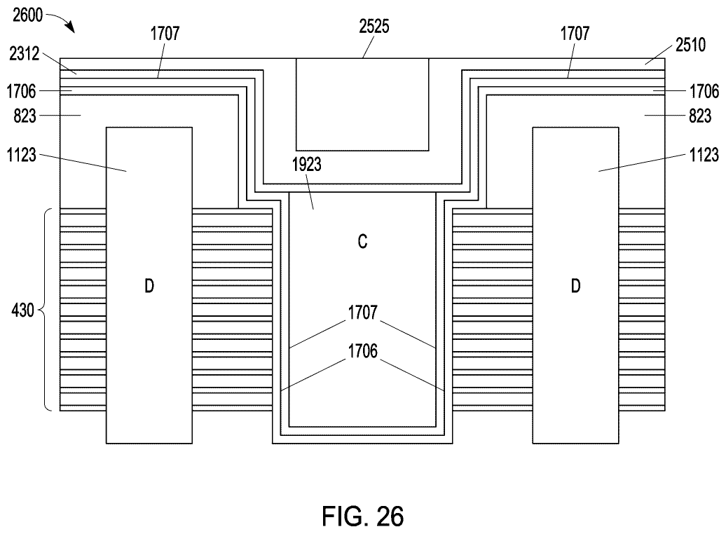

FIG. 26 is a cross-sectional view 2600 along reference line 1039 of FIG. 10, which is a view of structure 2500 in a direction substantially perpendicular to the view of FIG. 25, after further processing structure 2300 of FIG. 23. Cross-sectional view 2600 shows the relationship of material 2312 for a gate dielectric, polysilicon 2510, and metal 2525 directly above dielectric 1923 having center C after CMP, and location D in sacrificial material 1123 across the rows for the memory array.

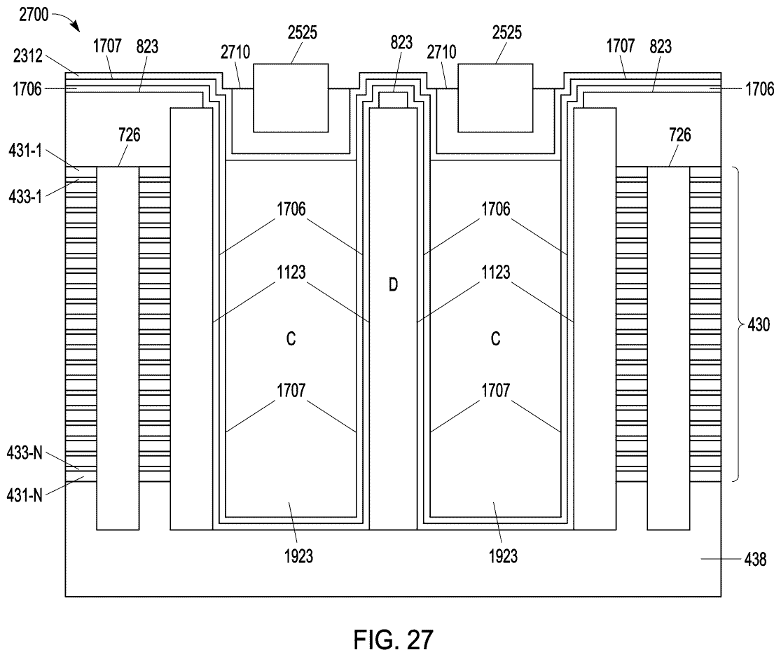

FIG. 27 is a cross-sectional view of a structure 2700 along reference line 539 of FIG. 10 after further processing structure 2500 of FIG. 25. Polysilicon of polysilicon 2510 that was on the surface of structure 2500 has been selectively wet etched, forming a gate structure 2710.

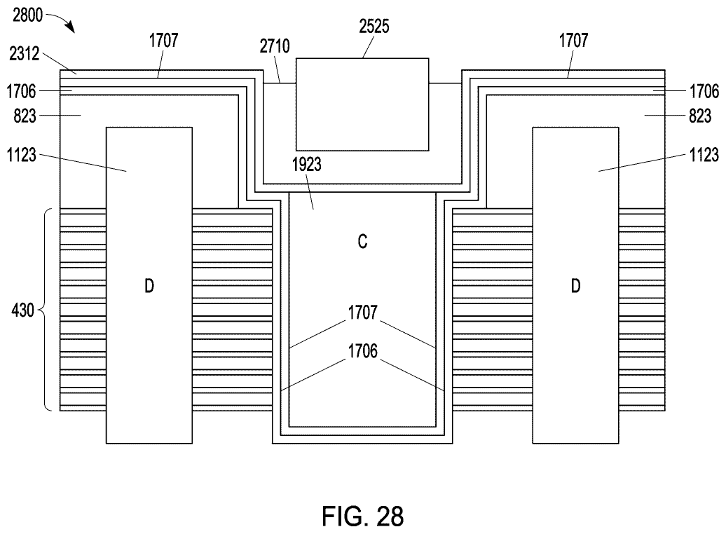

FIG. 28 is a cross-sectional view 2800 along reference line 1039 of FIG. 10, which is a view of structure 2700 in a direction substantially perpendicular to the view of FIG. 27, after further processing structure 2500 of FIG. 25. Cross-sectional view 2800 shows the relationship of gate structure 2710 directly above dielectric 1923 having center C and location D in sacrificial material 1123 across the rows for the memory array.

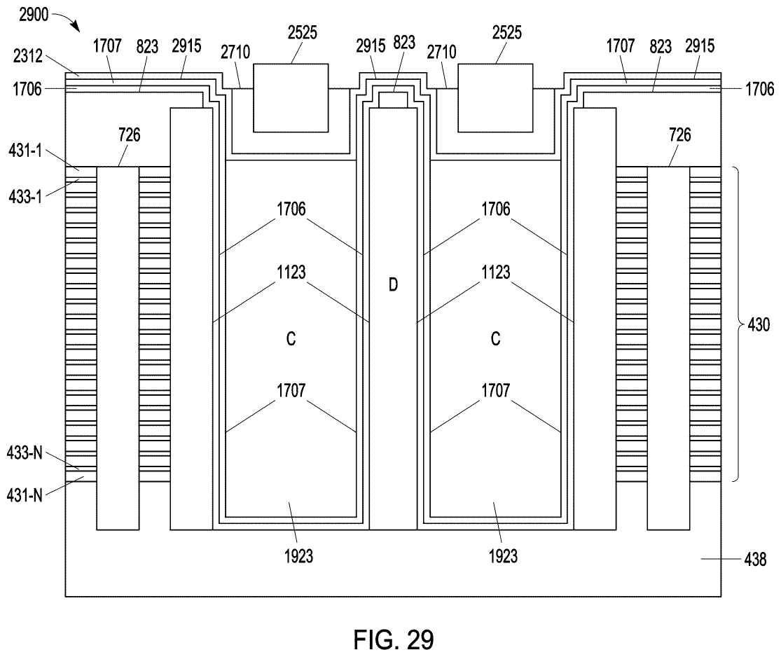

FIG. 29 is a cross-sectional view of a structure 2900 along reference line 539 of FIG. 10 after further processing structure 2700 of FIG. 27. Material 1707 for channels of the memory cells adjacent and horizontally below and contacting material 2312 for a gate dielectric, has been doped, forming doped surface channel regions 2915. The doping can be N+ doping. The doping can be performed by implant or other doping mechanism for this region.

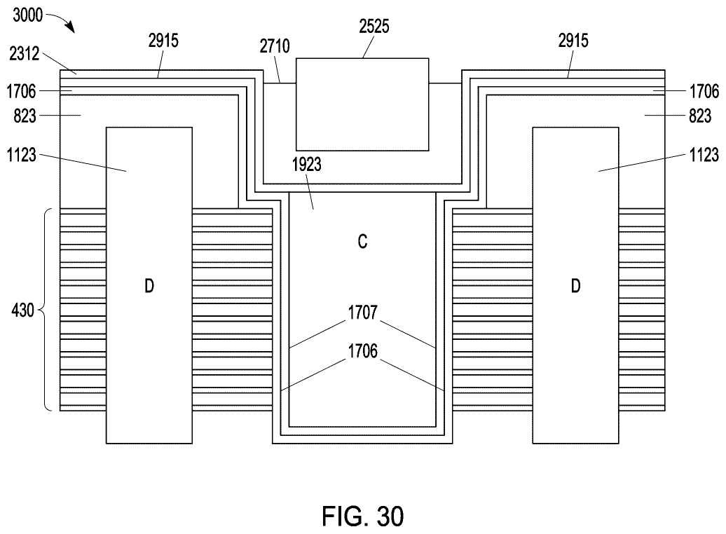

FIG. 30 is a cross-sectional view 3000 along reference line 1039 of FIG. 10, which is a view of structure 2900 in a direction substantially perpendicular to the view of FIG. 29, after further processing structure 2700 of FIG. 27. Cross-sectional view 3000 the relationship of the doped surface channel regions 2915 with respect to pillar locations having center C and location D in sacrificial material 1123 across the rows for the memory array.

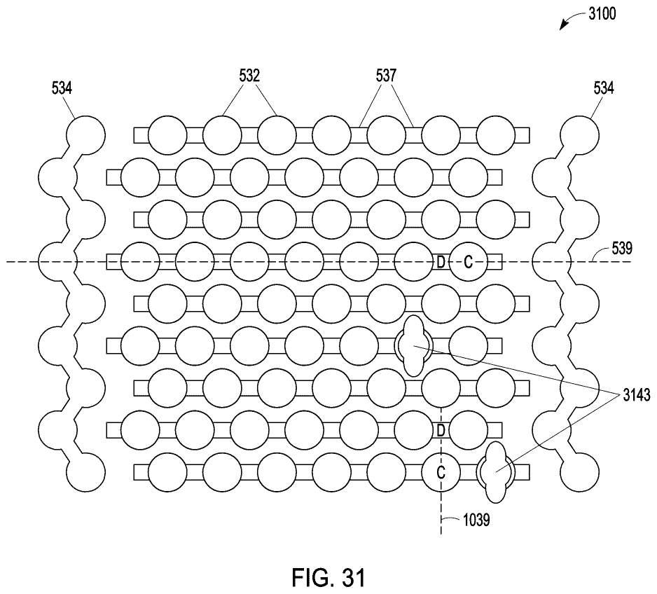

FIG. 31 illustrates a top view of a pattern 3100 showing second reference line 1039 in addition to reference line 539 of FIG. 5 with respect to a resist pattern. While reference line 539 is along a row of patterned row locations, reference line 1039 is in a direction across the patterned row locations. Locations C are at centers of the patterned pillar locations and locations D are at a mid-point between adjacent patterned pillar locations in the necked down regions. The resist pattern includes resist material 3143 formed on top of and across pillar locations above locations C, while not formed over the necked down regions above locations D. For ease of presentation, resist material 3143 is shown only by two positions, but are formed centered on each position of pillar openings 532.

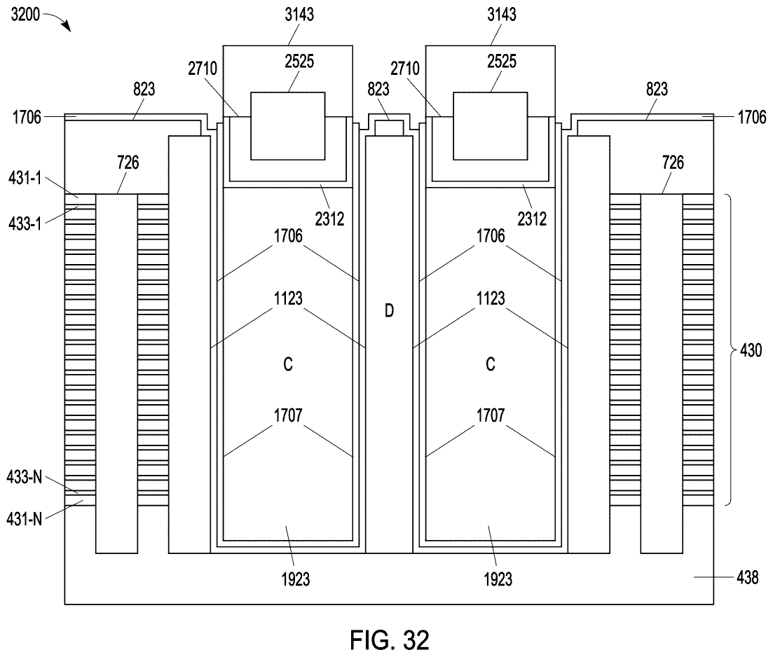

FIG. 32 is a cross-sectional view of a structure 3200 along reference line 539 of FIG. 31 after further processing structure 2900 of FIG. 29. Resist material 3143 has been formed on top of and across pillar locations above locations C, while not formed over the necked down regions above locations D. Resist material 3143 has been patterned and doped surface channel regions 2915 and surface portions of material 2312 for a gate dielectric contacting doped surface channel regions 2915 have been removed along direction of reference line 539 to isolate SGD drain contacts being formed by doped surface channel regions 2915 in direction of reference line 1039.

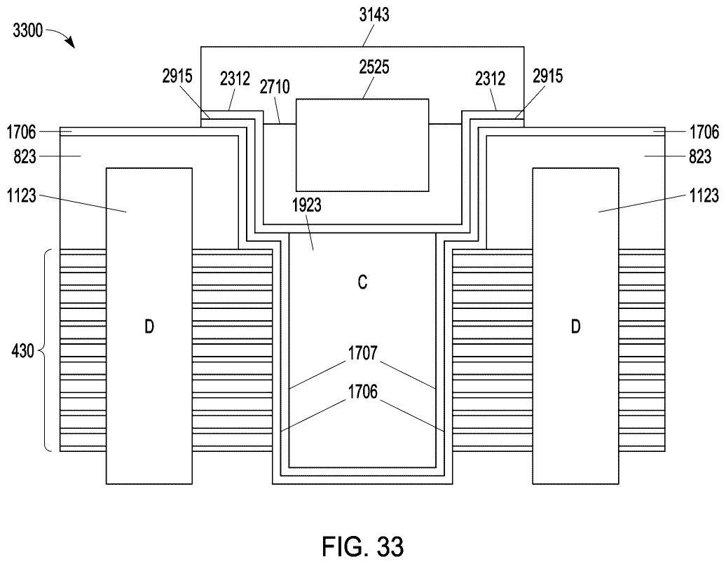

FIG. 33 is a cross-sectional view 3300 along reference line 1039 of FIG. 10, which is a view of structure 3200 in a direction substantially perpendicular to the view of FIG. 32, after further processing structure 2900 of FIG. 29. Cross-sectional view 3300 shows the relationship of doped surface channel regions 2915 for forming drain contacts with respect to pillar locations having center C and location D in sacrificial material 1123 across the rows for the memory array.

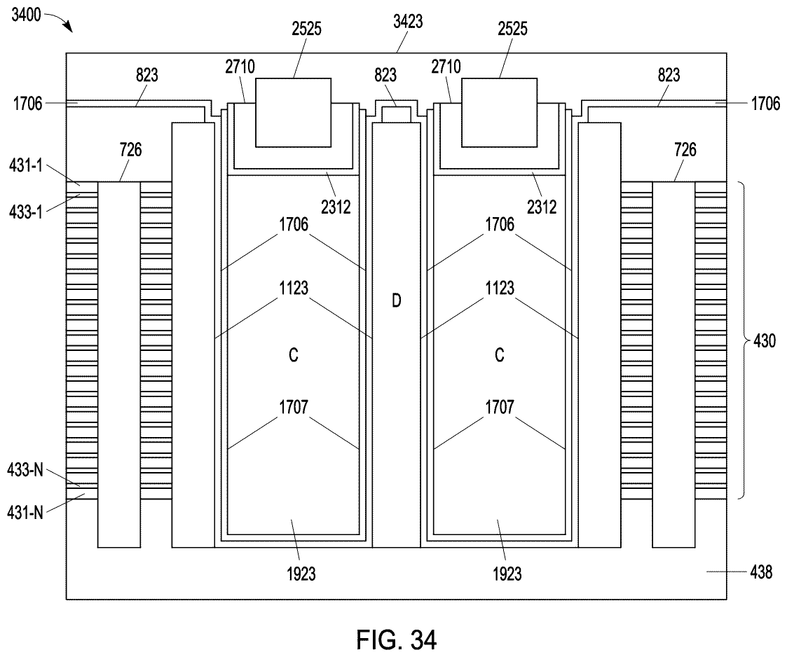

FIG. 34 is a cross-sectional view of a structure 3400 along reference line 539 of FIG. 31 after further processing structure 3200 of FIG. 32. The exposed surface of structure 3200 have been covered with dielectric 3423 and planarized. Dielectric 3423 can be an oxide such as, but not limited to, SiO_{X}.

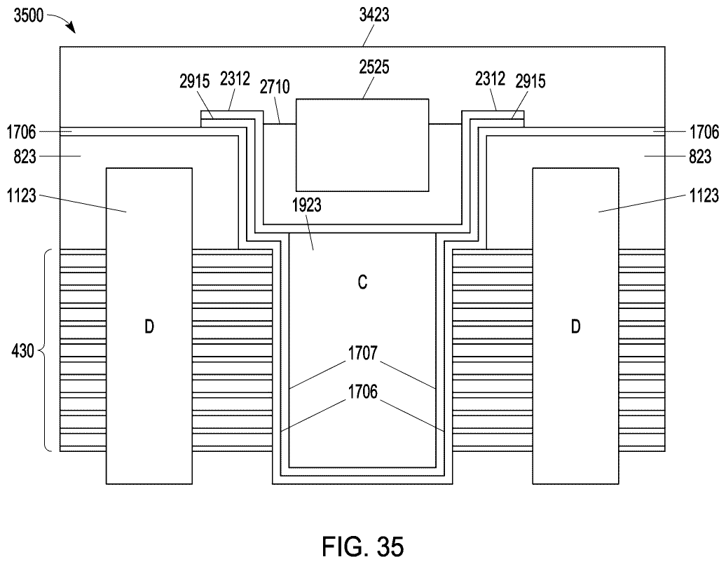

FIG. 35 is a cross-sectional view 3500 along reference line 1039 of FIG. 10, which is a view of structure 3400 in a direction substantially perpendicular to the view of FIG. 34, after further processing structure 3200 of FIG. 32. Cross-sectional view 3500 shows the relationship of pillar locations having center C and location D in sacrificial material 1123 with respect to dielectric 3423 across the rows for the memory array.

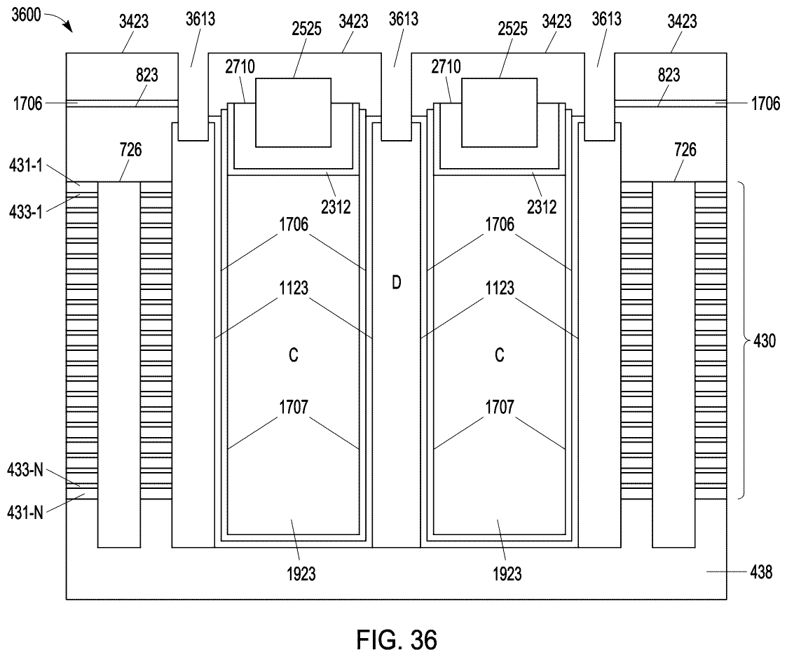

FIG. 36 is a cross-sectional view of a structure 3600 along reference line 539 of FIG. 31 after further processing structure 3400 of FIG. 34. The surface of structure 3400 has been patterned and holes 3613 have been etched above the necked down areas in sacrificial material 1123 about location D.

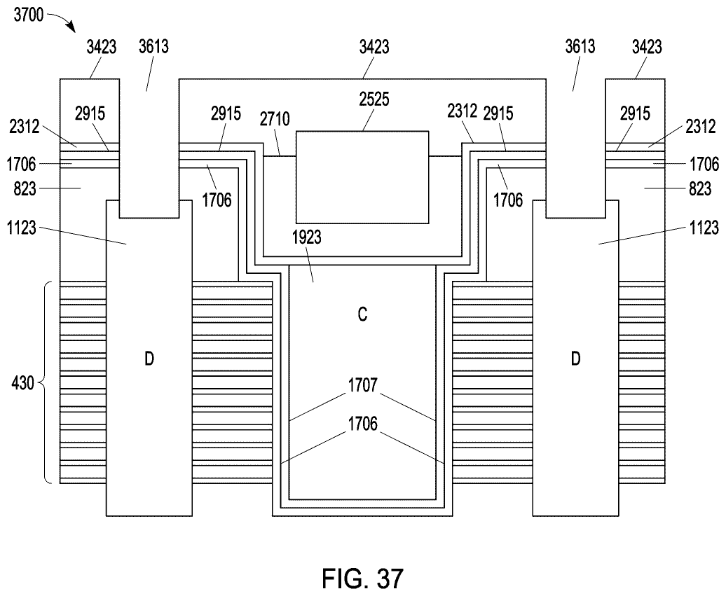

FIG. 37 is a cross-sectional view 3700 along reference line 1039 of FIG. 10, which is a view of structure 3600 in a direction substantially perpendicular to the view of FIG. 36, after further processing structure 3400 of FIG. 34. Cross-sectional view 3700 shows holes 3613 above sacrificial material 1123 having location D, without holes formed above pillar locations having center C.

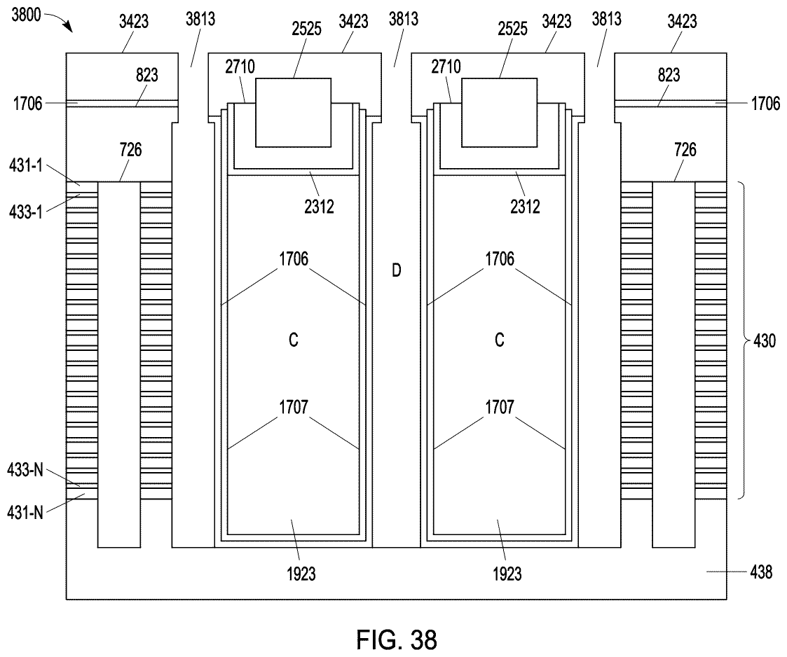

FIG. 38 is a cross-sectional view of a structure 3800 along reference line 539 of FIG. 31 after further processing structure 3600 of FIG. 36. Holes 3613 have been used to exhume sacrificial material 1123 in the necked down regions, forming holes 3813.

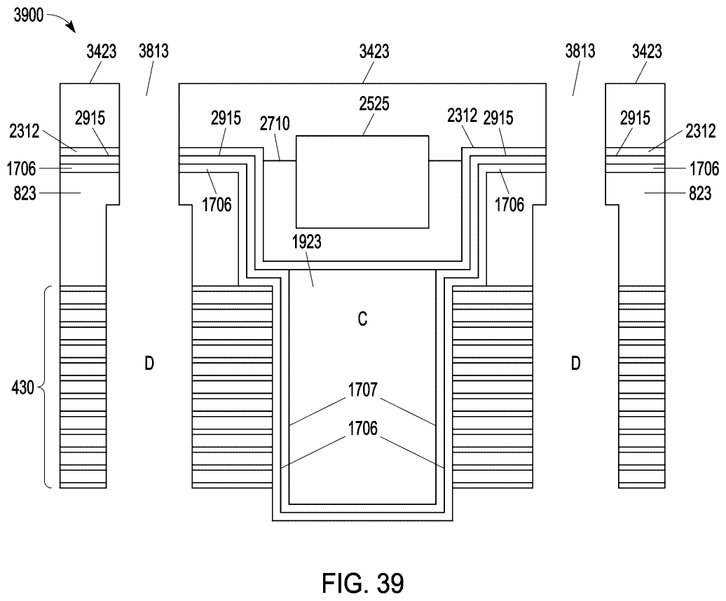

FIG. 39 is a cross-sectional view 3900 along reference line 1039 of FIG. 10, which is a view of structure 3800 in a direction substantially perpendicular to the view of FIG. 38, after further processing structure 3600 of FIG. 36. Cross-sectional view 3900 shows the relationship of holes 3813 about location D, without holes formed above pillar locations having center C, across the rows for the memory array.

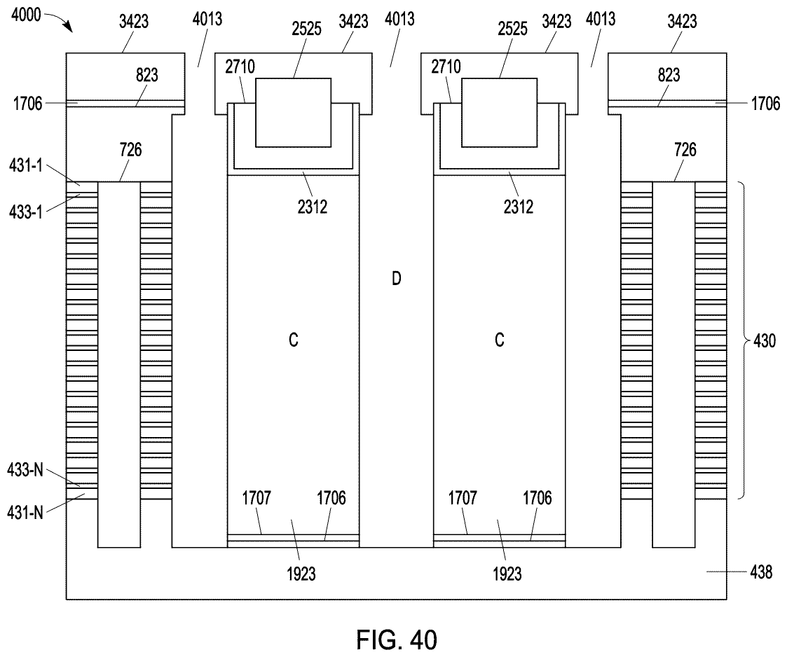

FIG. 40 is a cross-sectional view of a structure 4000 along reference line 539 of FIG. 31 after further processing structure 3800 of FIG. 38. Exposed material 1706 for memory cells and adjacent, contacting material 1707 for channels of the memory cells exposed by holes 3813 in the direction of reference line 539 have been removed by selectively etching, forming openings 4013. The material has been removed at the locations where the pillar openings 532 meet connection openings 537 of the necked down areas of pattern 500 of FIG. 5. For a pillar arranged as a circular cylinder, the removal forms the material for memory cells along the pillar as material for two memory cells of a tier at the pillar, the material for the two memory cells having two “C” shapes around the pillar separated from each other at the tier, and not a single circular shape around the pillar. Alternative processing can provide the pillar having material cell for a memory cell at a tier structured as a circular cross-section around the pillar, with the pillar having a SGD transistor substantially interior to the pillar.

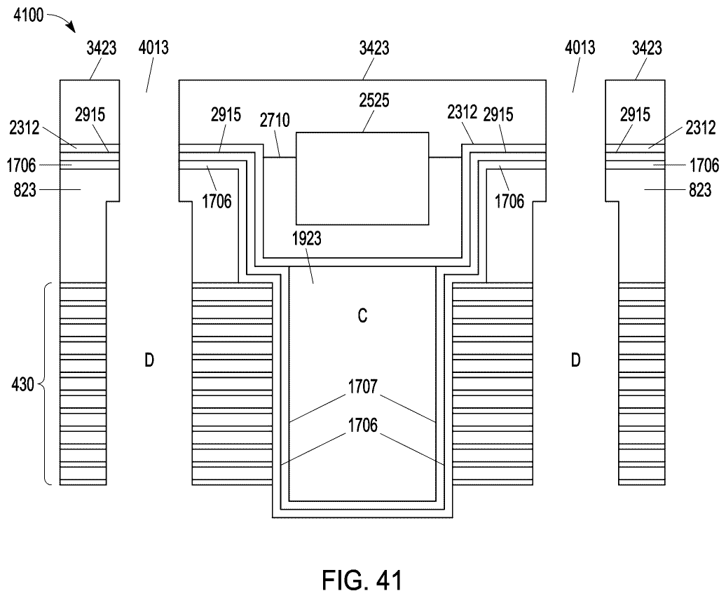

FIG. 41 is a cross-sectional view 4100 along reference line 1039 of FIG. 10, which is a view of structure 4000 in a direction substantially perpendicular to the view of FIG. 40, after further processing structure 3800 of FIG. 38. Cross-sectional view 4100 shows the relationship of pillar locations having center C with adjacent, contacting material 1707 for channels of the memory cells and material 1706 for memory cells and openings 4013 about location D, across the rows for the memory array.

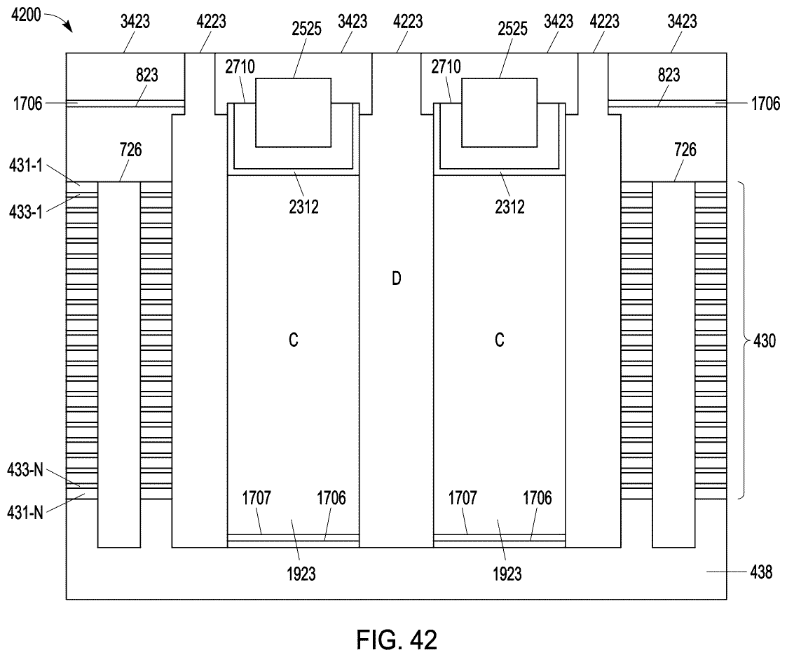

FIG. 42 is a cross-sectional view of a structure 4200 along reference line 539 of FIG. 31 after further processing structure 4000 of FIG. 40. Openings 4013 have been filled with dielectrics 4223 and the surface has been planarized after forming dielectrics 4223. Dielectric 4223 can be an oxide such as, but not limited to, SiO_{X}.

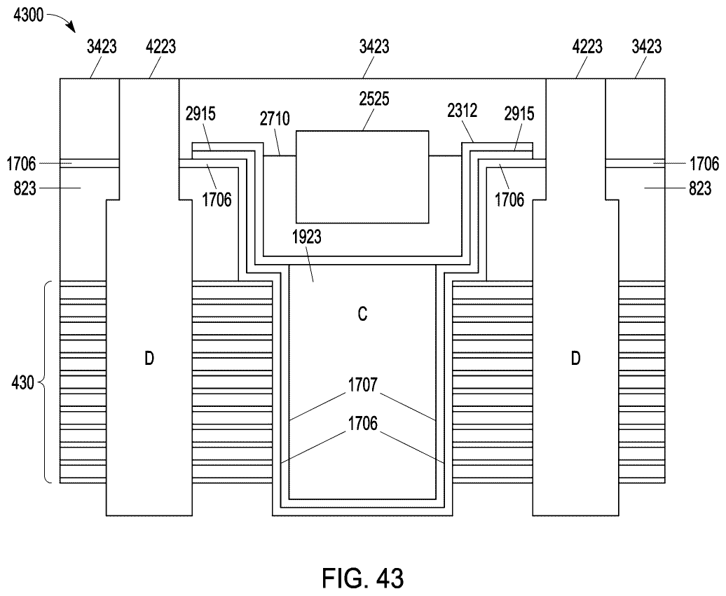

FIG. 43 is a cross-sectional view 4300 along reference line 1039 of FIG. 10, which is a view of structure 4200 in a direction substantially perpendicular to the view of FIG. 42, after further processing structure 4000 of FIG. 40. Cross-sectional view 4300 shows the relationship of pillar locations having center C and dielectrics 4223 about location D across the rows for the memory array.

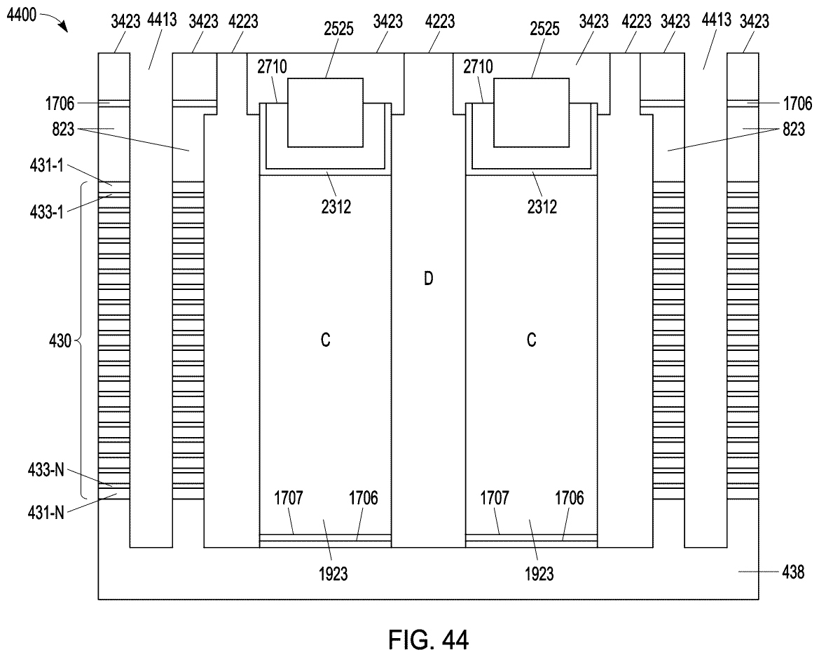

FIG. 44 is a cross-sectional view of a structure 4200 along reference line 539 of FIG. 31 after further processing structure 4200 of FIG. 42. The pattern of MPSs 534 having sacrificial fill 726 has been etched, removing sacrificial fill 726, dielectric material 823 on sacrificial fill 726, material 1706 for memory cells on dielectric material 823 above sacrificial fill 726, and dielectric 3423 on material 1706 for memory cells above sacrificial fill 726. Openings 4413 have been formed by removal of sacrificial fill 726, exposing nitride tiers 431-1 . . . 431-N and oxide layers 433-1 . . . 433-N of layers 430 in regions about MPSs 534. Material of pillar locations of the array and material of the necked down areas between pillar locations of the array have not been changed.

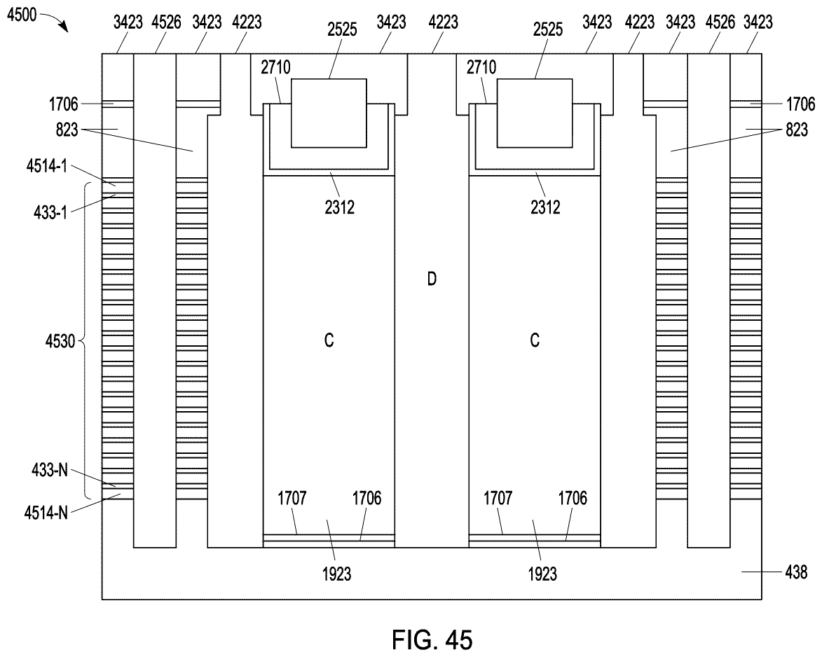

FIG. 45 is a cross-sectional view of a structure 4500 along reference line 539 of FIG. 31 after further processing structure 4400 of FIG. 44. Using openings 4413, nitride tiers 431-1 . . . 431-N have been exhumed using a selective etch to maintain oxide layers 433-1 . . . 433-N of layers 430. A replacement gate procedure has been conducted to replace nitride tiers 431-1 . . . 431-N with conductive layers 4514-1 . . . 4514-N at tier locations for memory cells. Conductive layers 4514-1 . . . 4514-N can be material for gates to memory cells at respective tiers and for access line conductors. The access line conductors can be etched back to isolate access lines. Conductive layers 4514-1 . . . 4514-N can be, but are not limited to, metal layers. The metal layers can include, but is not limited to, one or more of titanium nitride, tungsten, or molybdenum. At this part of the fabrication process, a high-k dielectric can be formed that is to be located between a gate and a blocking dilectric of individual memory cell. Openings 4413 have been filled with dielectric 4526 and the surface has been planarized.

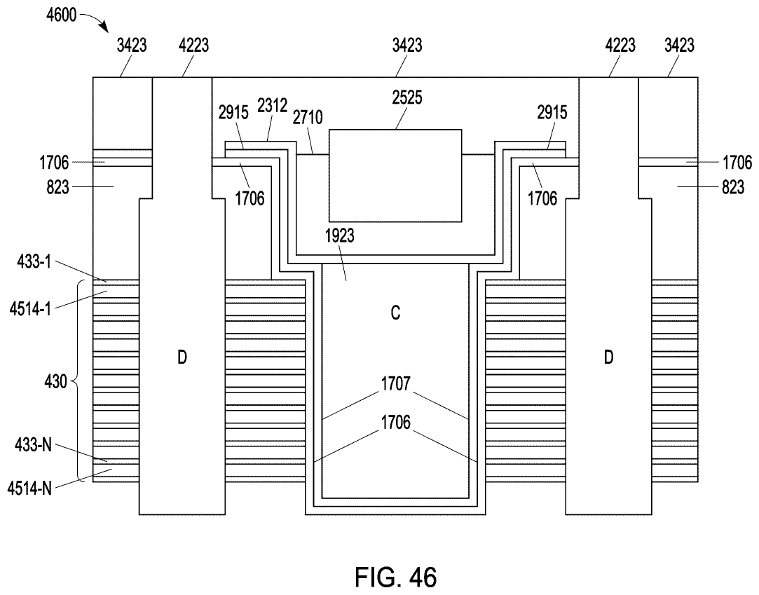

FIG. 46 is a cross-sectional view 4600 along reference line 1039 of FIG. 10, which is a view of structure 4500 in a direction substantially perpendicular to the view of FIG. 45, after further processing structure 4400 of FIG. 44. Cross-sectional view 4600 shows the relationship of conductive layers 4514-1 . . . 4514-N with pillar locations having center C with adjacent, contacting material 1707 for channels of the memory cells and material 1706 for memory cells and with dielectrics 4223 about location D in substantially perpendicularly adjacent necked down region, across the rows for the memory array.

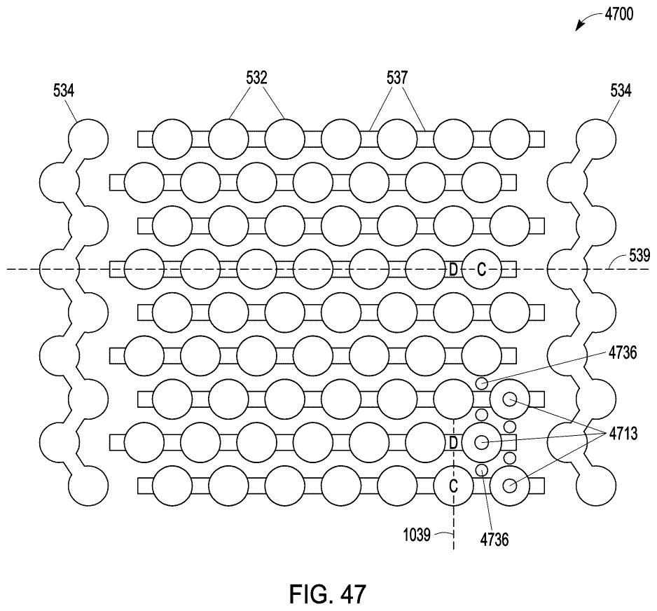

FIG. 47 illustrates a top view of a pattern 4700 showing second reference line 1039 in addition to reference line 539 of FIG. 5 with respect to openings associated with pillar locations and necked down areas between pillar locations. While reference line 539 is along a row of patterned row locations, reference line 1039 is in a direction across the patterned row locations. Openings 4713 are patterned at locations C at centers of the patterned pillar locations. Openings 4736 are patterned outside the pillar locations with two openings 4736 for each pillar location on opposite sides of the respective pillar location between the respective pillar location and the necked down areas of directly adjacent rows of pillar locations.

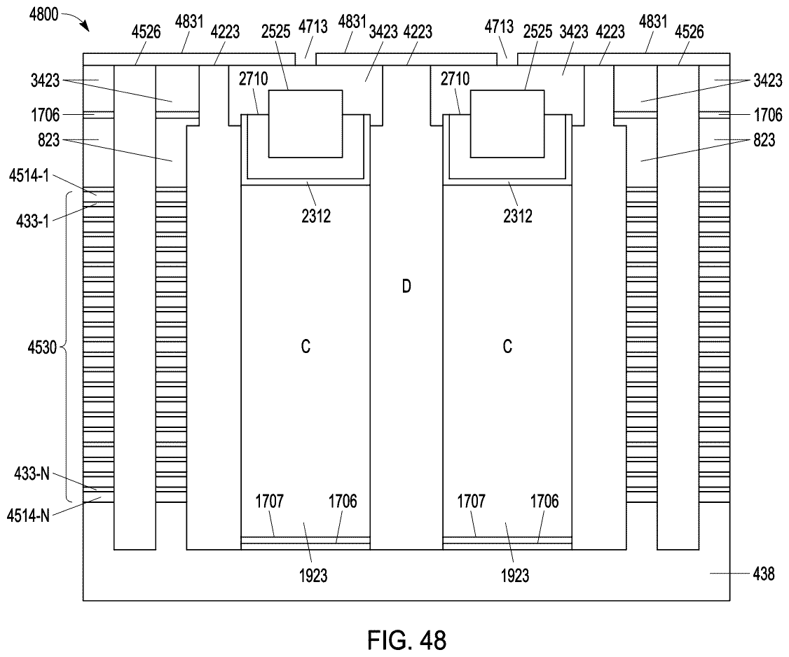

FIG. 48 is a cross-sectional view of a structure 4800 along reference line 539 of FIG. 47 after further processing structure 4500 of FIG. 45. A dielectric 4831 has been formed on the exposed surface of structure 4500. Dielectric 4831 can be formed by a deposition procedure. Dielectric 4831 can be a nitride layer such as, but not limited to, a layer of SiN_{X}. Openings 4713 and openings 4736 (shown in pattern 4700 of FIG. 47) have been formed by patterning and etching openings 4713 and openings 4736 through dielectric 4831 to allow dual damascene patterning access to form drain contacts and contacts to the SGD transistor.

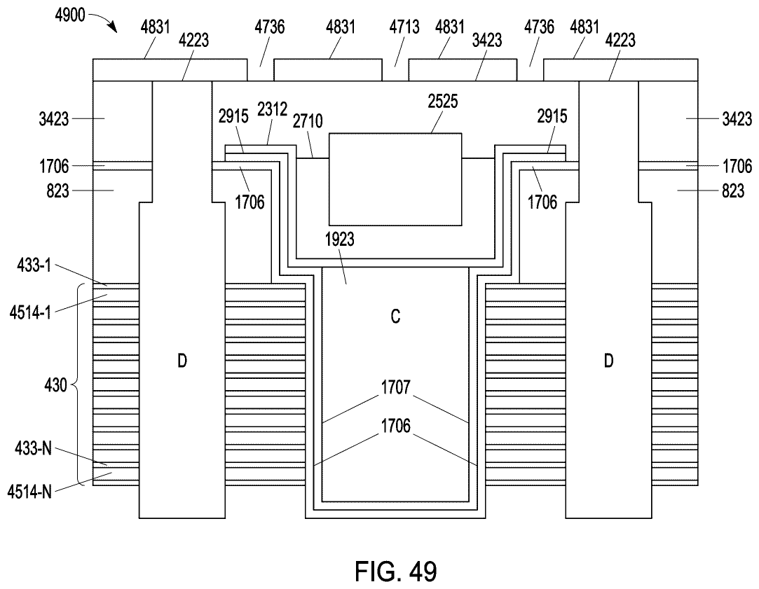

FIG. 49 is a cross-sectional view 4900 along reference line 1039 of FIG. 47, which is a view of structure 4800 in a direction substantially perpendicular to the view of FIG. 48, after further processing structure 4500 of FIG. 45. Cross-sectional view 4900 shows opening 4713 for a contact to a SGD transistor at the respective pillar location and openings 4736 for drain contacts of the SGD transistor. Opening 4736 is between pillar location having center C and dielectric 4223 about location D across the rows for the memory array.

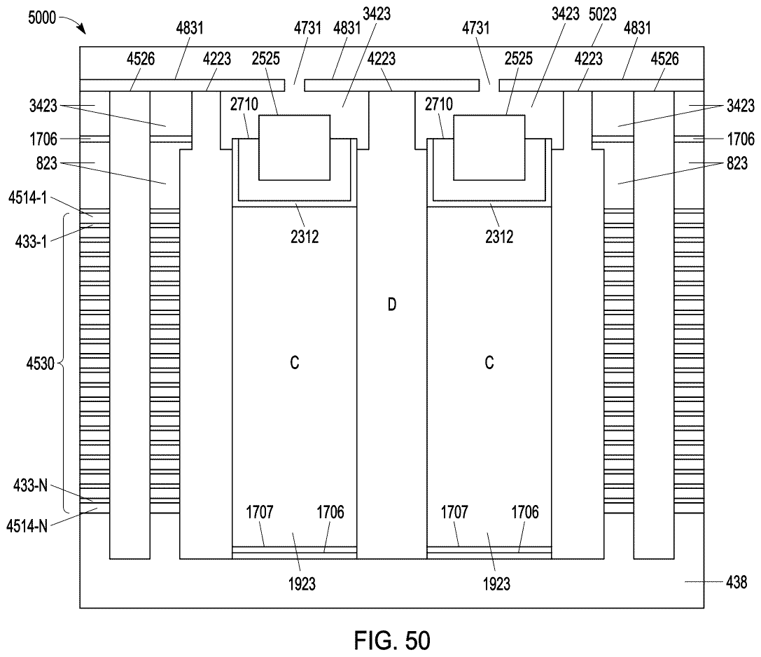

FIG. 50 is a cross-sectional view of a structure 5000 along reference line 539 of FIG. 47 after further processing structure 4800 of FIG. 48. A dielectric 5023 has been formed on the exposed surface of structure 4800. Dielectric 5023 can be formed by a deposition procedure. Dielectric 5023 can be an oxide layer such as, but not limited to, a layer of SiO_{X}. Openings 4713 have been filled, forming regions 4731 containing material of dielectric 5023.

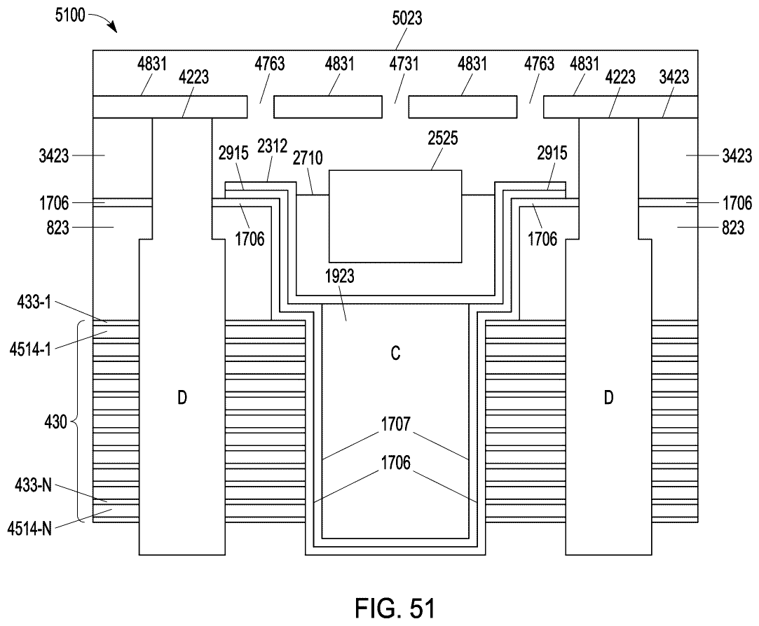

FIG. 51 is a cross-sectional view 5100 along reference line 1039 of FIG. 47, which is a view of structure 5000 in a direction substantially perpendicular to the view of FIG. 50, after further processing structure 4800 of FIG. 48. Openings 4736 have been filled, forming regions 4763 containing material of dielectric 5023. Cross-sectional view 5100 shows region 4731 for a contact to a SGD transistor at the respective pillar location filled by dielectric 5023 and regions 4763 for drain contacts of the SGD transistor filled by dielectric 5023, across the rows for the memory array.

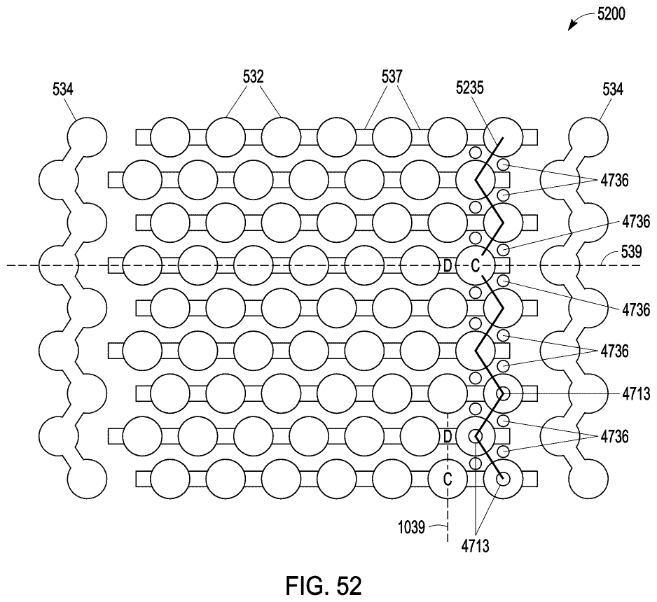

FIG. 52 illustrates a top view of a pattern 5200 showing second reference line 1039 in addition to reference line 539 of FIG. 5 with respect to contacts associated with pillar locations and necked down areas between pillar locations and a connection between contacts of pillar locations in multiple rows of the daisy chained pillar locations. While reference line 539 is along a row of patterned row locations, reference line 1039 is in a direction across the patterned row locations. Openings 4713 filled with dielectric 5023 are patterned at locations C at centers of the patterned pillar locations for contacts to SGD transistors interior to the pillars at respective pillar locations. Openings 4736 filled with dielectric 5023 are patterned outside the pillar locations with two openings 4736, filled with dielectric 5023, for each pillar location on opposite sides of the respective pillar location between the respective pillar location and the necked down areas of directly adjacent rows of pillar locations. A conductor line opening for conductive material 5235 connects an opening 4713 filled with dielectric 5023 at one pillar location with an opening 4713 filled with dielectric 5023 at one pillar location of a directly adjacent row of pillar locations. Conductor line opening for conductive material 5235 can extend across all rows of daisy chained pillars.

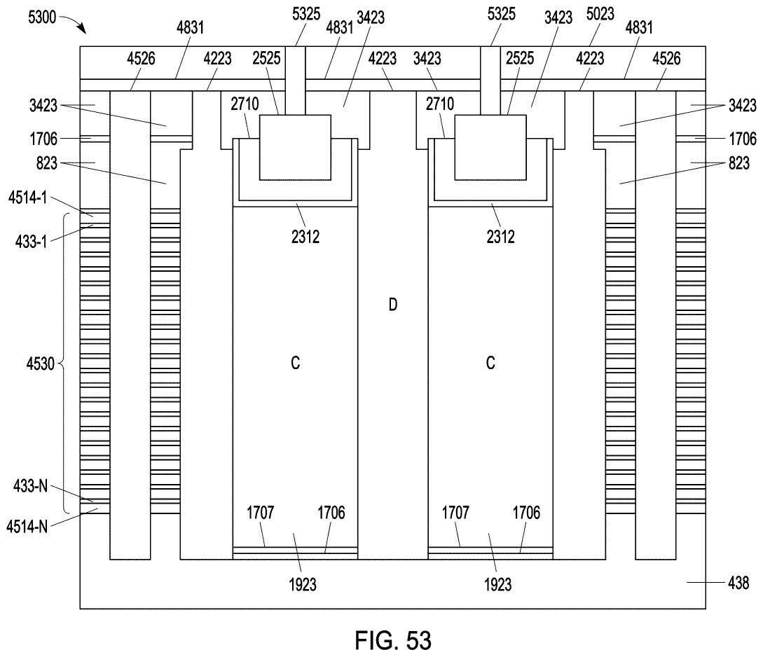

FIG. 53 is a cross-sectional view of a structure 5300 along reference line 539 of FIG. 52 after further processing structure 5000 of FIG. 50. Dual damascene SGD connections and drain contacts have been patterned and etched, using dielectric 4831 as etch stop. Conductive material 5325 has been formed in the opening at regions 4731 of structure 5000 of FIG. 50 for contacts to SGD transistor from the patterning and etching. Conductive material 5325 can include Ti, TiN, W, an ordered layering of Ti, TiN, and N, or other conductive material that can meet specifications for SGD transistors to pillars of memory cells in an array of a memory device. A CMP procedure has been applied to remove conductive material 5325 off of the top surface of dielectric 5023.

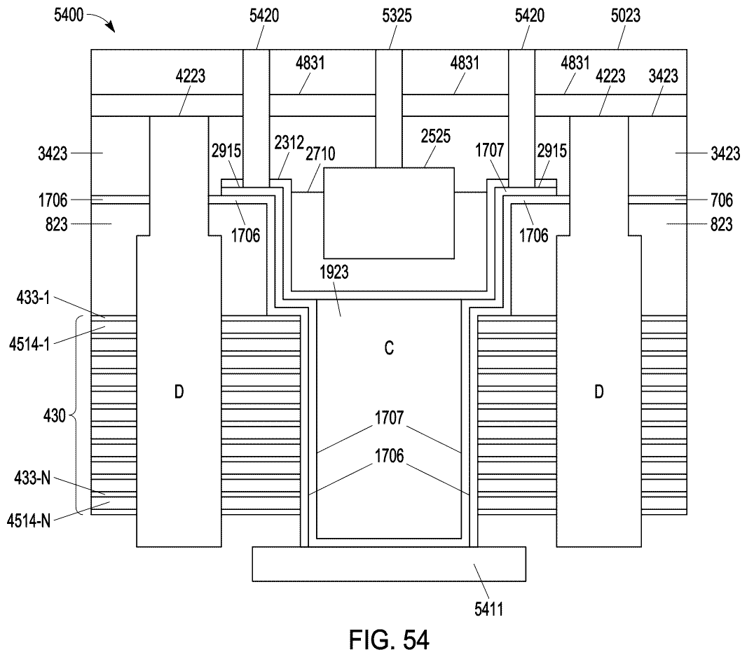

FIG. 54 is a cross-sectional view 5400 along reference line 1039 of FIG. 52, which is a view of structure 5300 in a direction substantially perpendicular to the view of FIG. 53, after further processing structure 5000 of FIG. 50. Conductive material 5420 has been formed at regions 4763 for drain contacts to channels of the SGD transistor, while forming conductive material 5325 at regions 4731 for contacts to SGD transistors. Cross-sectional view 5400 shows conductive material 5325 as a contact to the SGD transistor interior to the pillar having center location C and conductive material 5420 providing drain contacts to channels of the SGD transistors, across the rows for the memory array.

After forming conductive material 5325 and conductive material 5420 as contacts to the SGD transistors interior to the pillars of the rows of daisy chained pillars, the fabrication process can continue with back end of the line (BEOL) processing. A common source such as source 5411 of FIG. 54 coupled to material 1707 for channels of the memory cells can be formed in a backside source procedure post bonding for a memory array fabricated in a wafer-to-wafer technique for forming the memory device.

Various deposition techniques for components of structures in the process flow of FIGS. 4-54 can be used that are typical for the material being formed, the dimensions of the material being formed, and the architecture in which the material is being formed. Appropriate deposition techniques can include, for example, chemical vapor deposition (CVD), atomic layer deposition (ALD), variations of CVD and ALD, or other techniques. Selective etching can be used to remove selected regions in some of the processing discussed herein. Selective etching is a process in which one or more materials are removed from a structure, while one or more other materials remain in the structure with no or little removal. Selective etching can depend on the material to be etched, the material not to be etched, the etchant employed, and the method for etching. Types of etching can include wet etching and dry etching, where each of these two basic methods can include a number of different etching procedures. In addition, conventional masking techniques, providing protective regions in the processing, can be used in various material removal procedures, as taught herein.

In various embodiments, a memory device can include rows of pillars with each row configured as a daisy chain of pillars. The arrangement of each pillar can include a first vertical string of memory cells arranged in tiers along the pillar, a second vertical string of memory cells arranged in tiers along the pillar, and a SGD transistor structured substantially in the pillar at a level above the memory cells of the first and second strings. A cell channel of each memory cell of the first vertical string can be a portion of a first vertical channel structure to the pillar, where the first vertical channel structure to the pillar is vertically adjacent and contacting dielectric fill of the pillar. A cell channel of each memory cell of the second vertical string can be a portion of a second vertical channel structure to the pillar, where the second vertical channel structure to the pillar is vertically adjacent and contacting the dielectric fill of the pillar. The second vertical channel structure is separated from the first vertical channel structure by the dielectric fill. A SGD transistor can be structured substantially in the pillar at a level above the memory cells of the first and second strings. The SGD transistor can have a gate directly above the dielectric fill of the pillar, a first channel structure extending from the first vertical channel structure of the pillar, and a second channel structure extending from the second vertical channel structure of the pillar.

Variations of such a memory device its features, as taught herein, can include a number of different embodiments and features that may be combined depending on the application of such memory devices, the format of such memory devices, and/or the architecture in which such memory devices are implemented. Features of such memory devices can include the arrangement of each pillar having a first drain contact and a second drain contact, where the first drain contact is different from the second drain contact. The first drain contact can be disposed to operate with respect to the first channel structure of the SGD transistor, and the second drain contact can be disposed to operate with respect to the second channel structure of the SGD transistor.

Variations of such a memory device can include the gate of a SGD transistor of one row being coupled to the gate of another SGD transistor in another row by a conductive line. A memory cell at a given tier of the first string and a memory cell at the given tier of second first string can be coupled to a common access line. A data storage component of the memory cells of the first and second strings can be realized by a floating gate, a segmented dielectric charge trap region, or a continuous dielectric charge trap region.

Variations of such a memory device can include a first dielectric of the SGD transistor having a horizontal segment between a first vertical segment and a second vertical segment. The first vertical segment can be arranged as a gate dielectric between and contacting the first channel structure of the SGD transistor and the gate of the SGD transistor. The second vertical segment can be arranged as a gate dielectric between and contacting the second channel structure of the SGD transistor and the gate of the SGD transistor. The horizontal segment can be structured between and contacting the gate of the SGD transistor and the dielectric fill of the pillar.

Variations of such a memory device can include the gate of the SGD transistor being a n+ polysilicon gate and a contact to the SGD transistor can be coupled to the n+ polysilicon gate by titanium, titanium nitride, or tungsten. The contact to the SGD transistor can be substantially aligned with a center of the dielectric fill of the pillar.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and Internet-connected appliances or devices (e.g., Internet-of-Things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., a NVM device such as flash memory, ROM, an SSD, a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc.

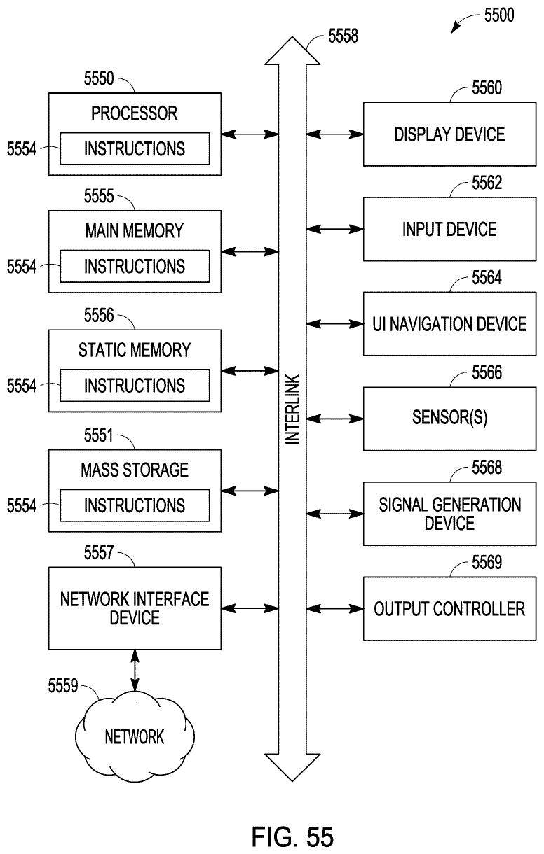

FIG. 55 illustrates a block diagram of an example machine 5500 having one or more embodiments of memory devices, as discussed herein, incorporated in machine 5500. In alternative embodiments, machine 5500 may operate as a standalone device or may be connected (e.g., networked) to other machines. In a networked deployment, machine 5500 may operate in the capacity of a server machine, a client machine, or both in server-client network environments. In an example, machine 5500 may act as a peer machine in peer-to-peer (P2P) (or other distributed) network environment. Machine 5500 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), or other computer cluster configurations. Example machine 5500 can include one or more memory devices having array structures with pillars arranged in daisy chains in rows of the array, as discussed with respect to memory device 100 of FIG. 1 and memory device 200 of FIG. 2, and structure 5300 of FIGS. 53 and 54.

Machine (e.g., computer system) 5500 may include a hardware processor 5550 (e.g., a CPU, a GPU, a hardware processor core, or any combination thereof), a main memory 5555 and a static memory 5556, some or all of which may communicate with each other via an interlink (e.g., bus) 5558. Machine 5500 may further include a display device 5560, an alphanumeric input device 5562 (e.g., a keyboard), and a user interface (UI) navigation device 5564 (e.g., a mouse). In an example, display device 5560, alphanumeric input device 5562, and UI navigation device 5564 may be a touch screen display. Machine 5500 may additionally include a mass storage (e.g., drive unit) 5551, a signal generation device 5568 (e.g., a speaker), a network interface device 5557, and one or more sensors 5566, such as a global positioning system (GPS) sensor, compass, accelerometer, or other sensor. Machine 5500 may include an output controller 5569, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 5500 may include a machine-readable medium on which is stored one or more sets of data structures or instructions 5554 (for example, software or microcode) embodying or utilized by machine 5500. Instructions 5554 may also reside, completely or at least partially, within main memory 5555, within static memory 5556, within mass storage 5551, or within hardware processor 5550 during execution thereof by machine 5500. In an example, one or any combination of hardware processor 5550, main memory 5555, static memory 5556, or mass storage 5551 may constitute machine-readable medium. Machine-readable medium can be a single medium or multiple media (e.g., a centralized or distributed database, or associated caches and servers) configured to store one or more instructions 5554.

The term “machine-readable medium” may include any medium that is capable of storing instructions for execution by machine 5500 and that cause machine 5500 to perform any one or more of the techniques for which machine 5500 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include (RAM), DRAM, SRAM, or SDRAM.

Instructions 5554 (e.g., software, programs, microcode, an operating system (OS), etc.) or other data stored on mass storage 5551, can be accessed by main memory 5555 for use by processor 5550. Main memory 5555 (e.g., DRAM) is typically fast, but volatile, and thus a different type of storage than mass storage 5551 (e.g., an SSD), which is suitable for long-term storage, including while in an “off” condition. Instructions 5554 or data in use by a user or machine 5500 are typically loaded in main memory 5555 for use by processor 5550. When main memory 5555 is full, virtual space from mass storage 5551 can be allocated to supplement main memory 5555; however, because mass storage 5551 is typically slower than main memory 5555, and write speeds are typically at least twice as slow as read speeds, use of virtual memory can greatly reduce user experience due to storage device latency (in contrast to main memory 5555, e.g., DRAM). Further, use of mass storage 5551 for virtual memory can greatly reduce the usable lifespan of mass storage 5551.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 5554 may further be transmitted or received over a network 5559 using a transmission medium via network interface device 5557 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 5557 may include one or more physical jacks (e.g., Ethernet, coaxial, or phone jacks) or one or more antennas to connect to the communications network 5526. In an example, network interface device 5557 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 5500 or data to or from machine 5500. The transportation can include using digital or analog communications signals that can be transmitted over the transmission medium to facilitate communication of such software or data.

The following are example embodiments of memory devices and methods, in accordance with the teachings herein.

An example memory device 1 can comprise a vertical string of memory cells, with each memory cell of the vertical string arranged in a tier along a pillar, with a cell channel of each memory cell being a portion of a vertical channel structure to the pillar. The vertical channel structure to the pillar is vertically adjacent and contacting dielectric fill of the pillar. A SGD transistor can be structured substantially in the pillar at a level above the memory cells. The SGD transistor can have a gate directly above the dielectric fill of the pillar and can have a channel structure extending from the vertical channel structure of the pillar.

An example memory device 2 can include features of example memory device 1 and can include the SGD transistor to include a first dielectric having a vertical segment arranged as a gate dielectric between and contacting the channel structure of the SGD transistor and the gate of the SGD transistor; and having a horizontal segment between and contacting the gate of the SGD transistor and the dielectric fill of the pillar.

An example memory device 3 can include features of any of the preceding example memory devices and can include the gate to include n+ polysilicon.

An example memory device 4 can include features of any of the preceding example memory devices and can include a contact to the SGD transistor substantially aligned with a center of the dielectric fill.

An example memory device 5 can include features of example memory device 4 and any of the preceding example memory devices and can include the contact to include titanium, titanium nitride, or tungsten.

An example memory device 6 can include features of any of the preceding example memory devices and can include the vertical channel structure to the pillar being structured around the pillar and each memory cell is structured around the pillar.

An example memory device 7 can include features of any of the preceding example memory devices and can include the memory cells and the pillar structured as a portion of one deck of multiple decks of tiers of memory cells.

In an example memory device 8, any of the memory devices of example memory devices 1 to 7 may be incorporated into an electronic apparatus further comprising a host processor or memory controller and a communication bus extending between the host processor/memory controller and the memory device.

In an example memory device 9, any of the memory devices of example memory devices 1 to 8 may be modified to include any structure presented in another of example memory device 1 to 8.

In an example memory device 10, any apparatus associated with the memory devices of example memory devices 1 to 9 may further include a machine-readable storage device configured to store instructions as a physical state, wherein the instructions may be used to perform one or more operations of the apparatus.

In an example memory device 11, any of the memory devices of example memory devices 1 to 10 may be formed or operated in accordance with any of the below example methods 1 to 9.

An example memory device 12 can comprise rows of pillars, arrangement of each pillar including: a first vertical string of memory cells arranged in tiers along the pillar, with a cell channel of each memory cell of the first vertical string being a portion of a first vertical channel structure to the pillar, the first vertical channel structure to the pillar vertically adjacent and contacting dielectric fill of the pillar; a second vertical string of memory cells arranged in tiers along the pillar, with a cell channel of each memory cell of the second vertical string being a portion of a second vertical channel structure to the pillar, the second vertical channel structure to the pillar vertically adjacent and contacting the dielectric fill of the pillar, the second vertical channel structure separated from the first vertical channel structure by the dielectric fill; and a SGD transistor structured substantially in the pillar at a level above the memory cells of the first and second strings, the SGD transistor having a gate directly above the dielectric fill of the pillar, and a first channel structure extending from the first vertical channel structure of the pillar, and a second channel structure extending from the second vertical channel structure of the pillar.

An example memory device 13 can include features of example memory device 12 and can include the arrangement of each pillar to include a first drain contact disposed to operate with respect to the first channel structure of the SGD transistor, and a second drain contact disposed to operate with respect to the second channel structure of the SGD transistor, the first drain contact being different from the second drain contact.

An example memory device 14 can include features of any of the preceding example memory devices and can include the gate of a SGD transistor of one row being coupled to the gate of another SGD transistor in another row by a conductive line.

An example memory device 15 can include features of any of the preceding example memory devices 12 to 14 and can include a memory cell at a given tier of the first string and a memory cell at the given tier of second first string being coupled to a common access line.

An example memory device 16 can include features of any of the preceding example memory devices 12 to 15 and can include a data storage component of the memory cells of the first and second strings to include a floating gate, a segmented dielectric charge trap region, or a continuous dielectric charge trap region.

An example memory device 17 can include features of any of the preceding example memory devices 12 to 16 and can include the SGD transistor to include a first dielectric having: a first vertical segment arranged as a gate dielectric between and contacting the first channel structure of the SGD transistor and the gate of the SGD transistor; a second vertical segment arranged as a gate dielectric between and contacting the second channel structure of the SGD transistor and the gate of the SGD transistor; and a horizontal segment between and contacting the gate of the SGD transistor and the dielectric fill of the pillar.

An example memory device 18 can include features of any of the preceding example memory devices 12 to 17 and can include the gate to include n+ polysilicon and a contact to the SGD transistor is coupled to the n+ polysilicon by titanium, titanium nitride, or tungsten.

An example memory device 19 can include features of any of the preceding example memory devices 12 to 18 and can include a contact to the SGD transistor is substantially aligned with a center of the dielectric fill.

In an example memory device 20, any of the memory devices of example memory devices 12 to 19 may be incorporated into an electronic apparatus further comprising a host processor or memory controller and a communication bus extending between the host processor/memory controller and the memory device.

In an example memory device 21, any of the memory devices of example memory devices 12 to 20 may be modified to include any structure presented in another of example memory device 12 to 20.

In an example memory device 22, any apparatus associated with the memory devices of example memory devices 12 to 21 may further include a machine-readable storage device configured to store instructions as a physical state, wherein the instructions may be used to perform one or more operations of the apparatus.

In an example memory device 23, any of the memory devices of example memory devices 12 to 22 may be formed or operated in accordance with any of the below example methods 1 to 9.

An example method 1 of forming a memory device can comprise forming a vertical string of memory cells, with each memory cell of the vertical string arranged in a tier along a pillar, with a cell channel of each memory cell being a portion of a vertical channel structure to the pillar, the vertical channel structure to the pillar vertically adjacent and contacting dielectric fill of the pillar; and forming a SGD transistor structured substantially in the pillar at a level above the memory cells, the SGD transistor having a gate directly above the dielectric fill of the pillar and having a channel structure extending from the vertical channel structure of the pillar.

An example method 2 of forming a memory device can include features of example method 1 of forming a memory device and can include forming a stack of materials for tiers of memory cells; forming rows of pillar openings in the stack of materials; forming openings in the stack of materials such that adjacent pillar openings in a row are connected by the openings, the openings being necked down in size relative to the pillar openings; forming memory cells and vertical channel structures in the pillar openings; forming the dielectric fill contacting the vertical channel structures in the pillar openings and forming gates above the dielectric fill; filling the openings that connected the pillar openings with a dielectric; and forming drain contacts between the gates and the dielectric in the openings that connected the pillar openings.

An example method 3 of forming a memory device can include features of example method 2 of forming a memory device and any of the preceding example methods of forming a memory device and can include forming multi-pillar slits at ends of the rows that extend in a direction generally perpendicular to the rows of pillar openings; and performing a replacement gate process to substitute gate material for material in the stack of materials at tier locations using the multi-pillar slits.

An example method 4 of forming a memory device can include features of example method 2 of forming a memory device and any of the preceding example methods of forming a memory device and can include forming the vertical channel structures in the pillar openings as first vertical channel structures and second vertical channel structures; and forming the drain contacts by forming two drain contacts per pillar, one of the two drain contacts coupled to the first vertical channel structure and a second one of the two drain contacts coupled to the second vertical channel structure.

An example method 5 of forming a memory device can include features of example method 2 of forming a memory device and any of the preceding example methods of forming a memory device and can include forming a conductive line coupling a gate in one row to a gate of another row.

In an example method 6 of forming a memory device, any of the example methods 1 to 5 of forming a memory device may be performed in forming a memory device further comprising forming a host processor and a communication bus extending between the host processor and a memory device.

In an example method 7 of forming a memory device, any of the example methods 1 to 4 of forming a memory device may be modified to include operations set forth in any other of example methods 1 to 4 of forming a memory device.

In an example method 8 of forming a memory device, any of the example methods 1 to 5 of forming a memory device may be implemented at least in part through use of instructions stored as a physical state in one or more machine-readable storage devices.

An example method 9 of forming a memory device can include features of any of the preceding example methods 1 to 6 of forming a memory device and can include forming features associated with any features of example memory devices 1 to 23.

An example machine-readable storage device storing instructions, that when executed by one or more processors, cause a machine to perform operations, can comprise instructions to perform functions associated with any features of example memory devices 1 to 23 or perform methods associated with any features of example methods 1 to 9 of forming a memory device. Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. The above description is intended to be illustrative, and not restrictive, and the phraseology or terminology employed herein is for the purpose of description. Combinations of the above embodiments and other embodiments will be apparent to those of skill in the art upon studying the above description.

What is claimed is:

1. A memory device comprising:
a vertical string of memory cells, with each memory cell of the vertical string arranged in a tier along a pillar, with a cell channel of each memory cell being a portion of a vertical channel structure to the pillar, the vertical channel structure to the pillar vertically adjacent and contacting dielectric fill of the pillar; and
a drain-side select gate (SGD) transistor structured substantially in the pillar at a level above the memory cells, the SGD transistor having a gate directly above the dielectric fill of the pillar and having a channel structure extending from the vertical channel structure of the pillar.

2. The memory device of claim 1, wherein the SGD transistor includes a first dielectric having:
a vertical segment arranged as a gate dielectric between and contacting the channel structure of the SGD transistor and the gate of the SGD transistor; and
a horizontal segment between and contacting the gate of the SGD transistor and the dielectric fill of the pillar.

3. The memory device of claim 1, wherein the gate includes n+ polysilicon.

4. The memory device of claim 1, wherein a contact to the SGD transistor is substantially aligned with a center of the dielectric fill.

5. The memory device of claim 4, wherein the contact includes titanium, titanium nitride, or tungsten.

6. The memory device of claim 1, wherein the vertical channel structure to the pillar is structured around the pillar and each memory cell is structured around the pillar.

7. The memory device of claim 1, wherein the memory cells and the pillar are structured as a portion of one deck of multiple decks of tiers of memory cells.

8. A memory device comprising:
rows of pillars, arrangement of each pillar including:
a first vertical string of memory cells arranged in tiers along the pillar, with a cell channel of each memory cell of the first vertical string being a portion of a first vertical channel structure to the pillar, the first vertical channel structure to the pillar vertically adjacent and contacting dielectric fill of the pillar;
a second vertical string of memory cells arranged in tiers along the pillar, with a cell channel of each memory cell of the second vertical string being a portion of a second vertical channel structure to the pillar, the second vertical channel structure to the pillar vertically adjacent and contacting the dielectric fill of the pillar, the second vertical channel structure separated from the first vertical channel structure by the dielectric fill; and
a drain-side select gate (SGD) transistor structured substantially in the pillar at a level above the memory cells of the first and second strings, the SGD transistor having a gate directly above the dielectric fill of the pillar, and a first channel structure extending from the first vertical channel structure of the pillar, and a second channel structure extending from the second vertical channel structure of the pillar.

9. The memory device of claim 8, wherein the arrangement of each pillar includes a first drain contact disposed to operate with respect to the first channel structure of the SGD transistor, and a second drain contact disposed to operate with respect to the second channel structure of the SGD transistor, the first drain contact being different from the second drain contact.

10. The memory device of claim 8, wherein the gate of a SGD transistor of one row is coupled to the gate of another SGD transistor in another row by a conductive line.

11. The memory device of claim 8, wherein a memory cell at a given tier of the first string and a memory cell at the given tier of second first string are coupled to a common access line.

12. The memory device of claim 8, wherein a data storage component of the memory cells of the first and second strings include a floating gate, a segmented dielectric charge trap region, or a continuous dielectric charge trap region.

13. The memory device of claim 8, wherein the SGD transistor includes a first dielectric having:
a first vertical segment arranged as a gate dielectric between and contacting the first channel structure of the SGD transistor and the gate of the SGD transistor;
a second vertical segment arranged as a gate dielectric between and contacting the second channel structure of the SGD transistor and the gate of the SGD transistor; and
a horizontal segment between and contacting the gate of the SGD transistor and the dielectric fill of the pillar.

14. The memory device of claim 8, wherein the gate includes n+ polysilicon and a contact to the SGD transistor is coupled to the n+ polysilicon by titanium, titanium nitride, or tungsten.

15. The memory device of claim 8, wherein a contact to the SGD transistor is substantially aligned with a center of the dielectric fill.

16. A method of forming a memory device, the method including:
forming a vertical string of memory cells, with each memory cell of the vertical string arranged in a tier along a pillar, with a cell channel of each memory cell being a portion of a vertical channel structure to the pillar, the vertical channel structure to the pillar vertically adjacent and contacting dielectric fill of the pillar; and
forming a drain-side select gate (SGD) transistor structured substantially in the pillar at a level above the memory cells, the SGD transistor having a gate directly above the dielectric fill of the pillar and having a channel structure extending from the vertical channel structure of the pillar.

17. The method of claim 16, wherein the method includes:
forming a stack of materials for tiers of memory cells;
forming rows of pillar openings in the stack of materials;
forming openings in the stack of materials such that adjacent pillar openings in a row are connected by the openings, the openings being necked down in size relative to the pillar openings;
forming memory cells and vertical channel structures in the pillar openings;
forming the dielectric fill contacting the vertical channel structures in the pillar openings and forming gates above the dielectric fill;
filling the openings that connected the pillar openings with a dielectric; and
forming drain contacts between the gates and the dielectric in the openings that connected the pillar openings.

18. The method of claim 17, wherein the method includes:
forming multi-pillar slits at ends of the rows that extend in a direction generally perpendicular to the rows of pillar openings; and
performing a replacement gate process to substitute gate material for material in the stack of materials at tier locations using the multi-pillar slits.

19. The method of claim 17, wherein the method includes:
forming the vertical channel structures in the pillar openings as first vertical channel structures and second vertical channel structures; and
forming the drain contacts by forming two drain contacts per pillar, one of the two drain contacts coupled to the first vertical channel structure and a second one of the two drain contacts coupled to the second vertical channel structure.

20. The method of claim 17, wherein the method includes forming a conductive line coupling a gate in one row to a gate of another row.
